(19) United States
(12) Patent Application Publication
(10) Pub. No.: US 2025/0291968 A1
(43) Pub. Date: Sep. 18, 2025

(54) DESTINATION AND ROUTE IDENTIFICATION FOR INPUT SIGNALS

(71) Applicant: T-Mobile USA, Inc., Bellevue, WA (US)

(72) Inventor: Mohamed Abdullah Amer, Bothell, WA (US)

(21) Appl. No.: 18/606,140

(22) Filed: Mar. 15, 2024

(51) Int. Cl. G06F 30/18

(52) U.S. Cl. CPC G06F 30/18

(57) ABSTRACT

A method can include generating, based on user attribute data, a plurality of period attributes vectors, each period attributes vector corresponding to a user of a plurality of users. A method can include determining, based on the plurality of period attributes vectors, a first set of nearest neighbors. A method can include generating, based on interaction data, a word embeddings matrix using a machine learning model. A method can include determining, using the word embeddings matrix, a second set of nearest neighbors that is a subset of the first set of nearest neighbors. A method can include determining, using historical user intents data, a historical user intents matrix. A method can include determining, based on the second set of nearest neighbors and the historical user intents matrix, one or more recommended intents for a user. In some implementations, a method can include determining a recommended user treatment.

### BACKGROUND

Conventionally, when a user calls or otherwise interacts with support personnel (e.g., through e-mail, text-based chat (e.g., text messaging, a chat feature, etc.), in store, etc.), the user can provide some input as to what issue they are experiencing or the reason for the interaction, for example by selecting from a dropdown list, selecting from several choices offered by a chatbot, selecting from a telephone menu, and so forth. However, these options are typically limited, and users can be routed to someone who is unable to resolve their issue. In some cases, users may find such interactions frustrating and press “0” or type a word such as “representative” into a text input to reach a human or otherwise take measures to reach a live user support representative without providing a clear indication of the reason they are reaching out.

Poor user routing can result in wasted time and expense for a company, such as a telecommunications service provider, frustrate the user, and so forth. For example, a user can become frustrated as they are transferred from one support representative to another until they reach someone who can help with their issue. Additionally, handoffs consume valuable support time, can result in dropped support calls, and so forth.

Poor understanding of user issues and poor understanding of user behaviors can have significant downsides for a business such as a telecommunications service, such as increased support costs, increased service cancelations, and lost sales opportunities. Accordingly, there is a need for improved approaches to understanding users, their interests, and their needs.

### BRIEF DESCRIPTION OF THE DRAWINGS

Detailed descriptions of implementations of the present invention will be described and explained through the use of the accompanying drawings.

FIG. 1 is a block diagram that illustrates a wireless communications system that can implement aspects of the present technology.

FIG. 2 is a block diagram that illustrates 5G core network functions (NFs) that can implement aspects of the present technology.

FIG. 3 is a block diagram of an example transformer.

FIG. 4 is a diagram that illustrates a journey according to some implementations.

FIG. 5 is a diagram that shows grouping of users according to their journeys.

FIG. 6 is a diagram that shows the application of the journey concept according to an implementation.

FIG. 7 shows a table of various users and various items.

FIG. 8 is a plot that shows a graphical depiction of vectorized representations of rankings.

FIG. 9 schematically illustrates a recommender system according to some implementations.

FIG. 10 is a block diagram that illustrates an example system and outputs according to some implementations.

FIG. 11 is a flowchart that illustrates an example process for determining top intents and top treatments according to some implementations.

FIG. 12 is a block diagram that illustrates an example process for determining and utilizing intents and treatments according to some implementations.

FIG. 13 is a block diagram that illustrates an example process for determined intents and treatments according to some implementations.

FIG. 14 is a block diagram that illustrates an example of a computer system in which at least some operations described herein can be implemented.

The technologies described herein will become more apparent to those skilled in the art from studying the Detailed Description in conjunction with the drawings. Embodiments or implementations describing aspects of the invention are illustrated by way of example, and the same references can indicate similar elements. While the drawings depict various implementations for the purpose of illustration, those skilled in the art will recognize that alternative implementations can be employed without departing from the principles of the present technologies. Accordingly, while specific implementations are shown in the drawings, the technology is amenable to various modifications.

### DETAILED DESCRIPTION

The description and associated drawings are illustrative examples and are not to be construed as limiting. This disclosure provides certain details for a thorough understanding and enabling description of these examples. One skilled in the relevant technology will understand, however, that the invention can be practiced without many of these details. Likewise, one skilled in the relevant technology will understand that the invention can include well-known structures or features that are not shown or described in detail, to avoid unnecessarily obscuring the descriptions of examples.

When a system receives an incoming signal, it can be important to route the signal to a correct destination. Incorrect routing can result in delays, signal losses, and so forth. Incorrect signal routing can place excess demands on the system, which may have limited resources. To mitigate this issue, additional resources can be provided, but this too can have a significant cost associated therewith. Thus, it is important to reduce occurrences of incorrect routing so that resources are not wasted attempting to resolve incorrect routing issues; thereby improving the efficiency of the system.

In some implementations, the approaches described herein can improve signal routing. For example, the approaches herein are used to predict an optimum route and automatically route an incoming signal according to the predicted route. As an example, when a system receives an incoming interaction (e.g., an incoming call, incoming text message, incoming e-mail, incoming chat session, and so forth), the system can predict a route for the incoming interaction and can use the predicted route to direct the incoming interaction to a solution provider. In some implementations, the approaches described herein can generate one or more suggested actions in response to the incoming interaction.

Incoming interactions can come from a variety of sources. Over time, the same source may initiate multiple incoming interactions. While there can be many sources, many possible routes, and many possible sequences of routes over time, patterns can nonetheless emerge. For example, sources with similar attributes may tend to initiate incoming interactions in similar manners, in similar sequences, via similar channels (e.g., phone call, text, chat, etc.) and so forth. Thus, by comparing sources and their interactions over time, similar sources can be identified. The interactions of these similar sources can be used to predict routing for a new incoming interaction.

For historical incoming interactions, various information can be known. For example, for each historical interaction, there may be source attribute information, optimum routing information (e.g., even if the source was incorrectly routed and required rerouting to get to the correct destination, the destination for the incoming interaction can be known), a detailed log of the interaction (e.g., including contents of the interaction), and so forth.

In some implementations, a multi-stage approach can be used to identify similar sources. For example, source attribute information can include basic information about the source and can be relatively simple to compare to identify similar sources. However, only comparing attributes may not provide a desired accuracy and predicting routing. In some implementations, the similar sources can be further compared to identify a final set of similar sources, the final set being a subset of the similar sources identified by comparing attributes. In some implementations, detailed interaction information can be used to determine the final set of similar sources. In some implementations, detailed interaction information can be large and/or complex. In some implementations, detailed interaction information can include transcripts of interactions or other complex information. In some implementations, a large language model can be used to process detailed interaction information prior to comparison.

In some cases, there can be a very large number of users and/or a very large number of interactions. Thus, identifying similar sources can be prohibitively computational demanding if identifying similar sources is done in an exact manner. In some implementations, attributes data and/or detailed interaction information can be converted to a vectorized format, and approximate nearest neighbor approaches can be used to identify similar vectors. In some embodiments, vectors can be simplified by reducing the number of dimensions of the vectors, for example by rotating the vectors. In some implementations, principal components analysis or other approaches can be used to reduce the dimensionality of vectors.

As an example, consider customer service interactions in a wireless telecommunications company, in which the sources are users and incoming interactions can be, for example, phone calls, text messages, chats, emails, in-person interactions, and so forth. There can be many sources (customers), and the sources can have various attributes (e.g., age, time with service, average bill, payment status, services, lines, devices, etc.).

Providing quality user service is important for ensuring that users remain content with the services they receive. Poor user service can result in attrition (“churn”), repeated service calls, reputational damage, and so forth. Significant expenses can be incurred when users receive poor service. For example, if a call or other interaction has to be routed to multiple service representatives before an issue is resolved, or if a user has to make multiple inquiries (e.g., calls, texts, emails, etc.), user satisfaction can be reduced, significant demand can be placed on user service resources, which can require greater staffing, resulting in longer waits times for other users, and so forth.

Providing quality user service can be especially difficult in some industries. For example, wireless telecommunications companies may offer a variety of services (e.g., wireless voice, wireless data, wireless high speed home internet (HSI), international calling, international data, and so forth), have users using a wide variety of hardware (e.g., HSI gateways, smartphones, tablets, smartwatches, laptops, etc.) and software (e.g., iOS, iPadOS, watchOS, Android, Windows, and so forth), and so forth. In some cases, a wireless telecommunications service may also be a retailer of certain consumer goods such as smartphones, hotspots, accessories, and so forth. Users can contact support regarding hardware issues, software issues, network issues, billing issues, payment issues, to ask questions about services and/or products, and so forth. Users may call about issues with existing services, hardware, and/or software, and/or may call to inquire about adding new services, purchasing a new device, and so forth.

Reasons for interaction requests (intents) can depend on a large number of factors, such as the services a user are subscribed to, the hardware they are using, the software they are using, their geographic location, their account status (e.g., paid in full or delinquent), their usage patterns (e.g., whether or not a user travels internationally or uses hotspot functionality), and so forth. As one example of the impact of geographic location, there may be an outage in one area because of adverse weather, network maintenance, high demand due to an emergency or event, and so forth, while other geographic locations may be unaffected. As an example of service interruptions, one service (e.g., voice calling) may be functioning normally while another (e.g., wireless HSI) may be experiencing issues. In another example, a user may experience an issue with hardware or software of their smartphone or other device. In other cases, users may initiate an interaction because they have a billing inquiry, would like to add a remove a service (e.g., wireless hotspot service, international data, adding or removing a line, etc.), and so forth.

As described above, users can contact a telecommunications company for a wide variety of support issues, purchase inquiries, and so forth. It can be important to route a user to an appropriate solution provider who can assist them with their issue or inquiry. Correctly directing users can reduce call times, reduce service costs, increase sales, and so forth. User satisfaction can be increased, user frustration can be reduced, churn can be reduced, and so forth. In some implementations, a recommender system as described herein can direct users to self-support services, such as documentation on the company's web site or a chat bot that utilizes artificial intelligence and/or machine learning to process inquiries and provide guidance. Thus, the solution provider need not be an individual.

While described largely in the context of existing users, it will be appreciated that the techniques described herein can also, in some cases, be applied to prospective users. For example, information about prospective users (e.g., age, income, location, employment, and/or any other demographic information) can be used to identify services that prospective users may be interested in, for example by comparing them with similar existing users.

In some implementations, the approaches described herein can be used when a user reaches out to a company. However, the approaches herein are not so limited. In some cases, the approaches used herein can be used by the company to proactively reach out to users. For example, if a user is likely to want to upgrade their device (e.g., smartphone) when a new model is released, the company can proactively reach out with an offer that may be attractive to the user. As another example, if a user appears likely to churn, the company can proactively reach out with an offer for discounted service, a discount on a new device, and so forth.

The techniques herein can be used to recommend intents, treatments, or both for users, which can include current users and/or prospective users. Intents can describe the reason a user reaches out to a company, such as to add a line, to inquire about a bill, to cancel service, and so forth. Treatments can describe actions that are proactively taken by the company, such as suggesting the user add a line, offering a promotion, and so forth. Treatments can be appealing because they allow the company to take action before a customer has made a decision. As an example, if a user is likely to call in the near future to cancel service, the company can proactively make an offer to the customer in an effort to retain them before they have made the decision to cancel, which can lead to reduced churn.

In some approaches, an ensemble of binary classification ML models can be used to predict a likelihood that a user contacts a company for a particular intent, that a user would be receptive to a particular treatment, and so forth. For example, the ensemble of binary classification models can include a model to predict a likelihood that an intent is cellular churn, while other binary classification models can predict that the intent is bill inquiry, HSI churn, network performance, and so forth. Such an approach can be advantageous because it is relatively cheap and fast to implement and can provide useful guidance. However, such an approach typically models less than all possible intents and/or treatments (e.g., a separate model must be trained for each covered intent and/or treatment), may not capture interrelationships between actions, may not consider sequential decision making (e.g., a user who initiates an interaction about A may also be interested in B and C or is likely to initiate interactions about D and E in the future), may use different predictors, and/or may exhibit ranking issues. For example, such an approach may be able to predict that a user is calling with a billing inquiry, but such an approach may fail to predict that the user is also interested in adding a service (e.g., adding a line, adding hotspot coverage, adding international roaming, etc.), may also be interested in upgrading their device, and so forth.

When an ensemble of models is used to determine intents, ranking issue may arise. Ranking issues can make it difficult to determine which intent is most likely. For example, binary classification models can be configured to output a number between 0 and 1, where 0 indicates a low likelihood (e.g., a user is likely not initiating an interaction about billing) and 1 indicates a high likelihood (e.g., a user likely is initiating an interaction about billing). If a billing classification model outputs a value of 0.7 and a network service classification model outputs a value of 0.8, this does not necessarily indicate that the user is more likely to be calling about network service, as the output values for different models can vary for a wide number of reasons, and one model may output a lower value even though the actual likelihood of the user having the corresponding intent is higher.

Described herein are approaches that can predict intents and/or treatments without being restricted to a limited set of intents and/or treatments. In some implementations, the approaches herein can be used to predict multiple intents and/or treatments. Often, users with similar attributes behave in similar manners. For example, users with similar numbers of lines, similar data usage, similar hotspot usage, similar balances, similar signup dates, similar hardware, similar incomes, similar ages, and so forth can behave in similar ways. This insight can be used to predict a user's journey. The journey can represent the behavior of users over time. For example, consider user A, who signed up three years ago with a particular plan, has two lines, and has upgraded one line's smartphone each year, and user B, who signed up two years ago with the same plan, also has two lines, and has also upgraded one's smartphone line each year. Based on user A's journey, it can be predicted that user B is likely to upgrade a smartphone in the next year. As another example, consider user C in a geographic area and user D in the same geographic area, both having similar usage patterns. If user C recently signed up for HSI service, it may be likely that user D would also be interested in HSI service.

The preceding examples illustrate identifying one step ahead in a user's journey, but the approaches herein are not so limited. In a larger context, many users may be on the same journey, with different users at different points along the journey. By looking at users who are further along in the journey, a particular user's next steps in the journey can be predicted. For example, a user's next one step, two steps, three steps, four steps, or more can be predicted.

In some implementations, a context-aware, user-based collaborative filtering recommender system and related methods can be used to predict and/or evaluate user intents and/or treatments. In a context-aware approach as described herein, users can be grouped together based on their journeys. Users that share a journey can have similar behaviors, similar attributes, and so forth. Such an approach can offer a number of advantages. For example, context-aware approaches can consider all possible events (e.g., as opposed to being trained only on specific events), consider interrelationships between user behaviors, can recommend one or more next intents and/or treatments based on the behavior of similar users (e.g., users on the same journey), use a single unified list of attributes, handle cold start problems (e.g., where little is known about the particular user, for example because they are new, have not provided a lot of information, rarely interact with user support, etc.) because it is context aware, provide transparency and interpretability (e.g., if implemented without the use of deep learning and/or using approaches such as the Two Towers model known to those of skill in the art), utilize transcripts and/or summaries (e.g., call transcripts, email transcripts, chat transcripts, summaries of in-store interactions, etc.) for greater insight, and so forth.

However, a naïve implementation of such a recommender system can have several drawbacks. Vector representations of, for example, user attributes, transcripts, and so forth can be high-dimensional, requiring large computing resources (e.g., GPU time, CPU time, storage, memory) and potentially compromising results. Accordingly, there is a need to implement a recommender system in a manner that provides reliable results without suffering from commercially infeasible storage requirements or computational complexity and without taking too long to obtain results.

In some implementations, a recommender system can operate in stages, with relatively simple processing being carried out on a large number of records (e.g., on all users or sources) and computationally intensive processing being carried out on a smaller number of records (e.g., only on users or sources that are similar to a user or source being analyzed by the recommender system, or only users or sources within a group of similar users or sources).

In some implementations, a system can be configured to predict intents, treatments, or both based on user journeys. In some implementations, a system can be configured to output a particular number of journeys, and users can be grouped by similarity to create the desired number of journeys. In some implementations, journeys can have a particular size (e.g., a particular number of users or sources or a number of users or sources in a particular range).

Different types of data can be used to identify similar users that are on the same journey. Some data can be relatively simple, for example user attributes, historical treatments, historical intents, and so forth, while other data can be relatively complex, such as transcripts of calls, chats, in-person support records, emails, text messages, and so forth. Identifying similarity in complex data can be computationally intensive. Thus, in some implementations, as a starting point for identifying users on the same journey, relatively simple data can be used. For example, in some implementations, a large number of users can be reduced by considering user attributes. Users can have many attributes, such as age, credit score, income, time with service, bill amount, payment status (e.g., current, 30 days delinquent, 60 days delinquent, etc.), location, number of lines, number of services, types of services, types of devices (e.g., smartphones, watches, tablets, hotspots, etc.), data usage, roaming usage, international usage, whether they recently added a line, recently bought a new device, brought their own device, and so forth. While there can be a large number of attributes, the number of attributes can be small compared with, for example, call data.

In some implementations, a system can use attribute data to generate period attributes vectors. The period attributes vectors can describe attributes over a number of periods, for example one period, two periods, three periods, five periods, ten periods, twenty periods, or more, or any number between these numbers, or more. The number of periods can indicate, for example, a time range, a number of interactions, and/or the like. In some implementations, the period attributes vectors can be determined for all users (e.g., all customers of a telecommunications service).

In some implementations, the system can use an intrinsic dimension transformer to simplify the period attributes vectors. The intrinsic dimension transformer can perform, for example, principal components analysis and/or other methods to, for example, rotate the period attributes vectors, which can simplify the vectors (e.g., reduce the dimensionality of the vectors). While such approaches can cause some loss of information, the transformed vectors may nonetheless still be used to provide valuable insight for identifying similar users.

In some implementations, the system can determine a first set of nearest neighbors. In some implementations, the first set of nearest neighbors can be determined based on the transformed period attributes vectors. In some implementations, the intrinsic dimension transformer may not be used, and nearest neighbors can be determined based on the period attributes vectors. The users identified at this stage may be, but are not necessarily, on the same journey.

In some implementations, the number of period attributes vectors can be very large (e.g., millions, tens of millions, hundreds of millions, or more). Thus, exact determination of nearest neighbors, for example using linear searching or space partitioning, can in some cases be too computationally expensive to carry out. Moreover, exact determination of nearest neighbors may not be necessary to group users into journeys with a desired level of accuracy. Accordingly, in some implementations, approximate nearest neighbor methods can be used to identify nearest neighbors, such as locality-sensitive hashing (LSH), hierarchical navigable small world (HNSW), inverted file with flat compression (IVFFlat), and so forth. In some implementations, an algorithm such as ANNOY can be used to identify approximate nearest neighbors. In some implementations, Euclidean distance, Manhattan distance, cosine similarity, or another similarity metric can be used in determining approximate nearest neighbors. In some implementations, which distance metric to use can be selected based on performance, input data, and/or other considerations.

The first set of nearest neighbors can be a set of users that is significantly smaller than the set of all users (for example, 50% smaller, 60% smaller, 70% smaller, 80% smaller, 90% smaller, 95% smaller, 99% smaller, etc.), depending upon the particular implementation. In some implementations, more complex, computationally intensive, and/or time intensive calculations can be performed to determine the second set of nearest neighbors. These calculations can include, for example, determining similarity based on vector representations of user interactions (e.g., calls, texts, emails, in-store interactions, etc.). Such vector representations can be dense, relatively large, etc. In some implementations, only users included in the first set of nearest neighbors may be used to determine the second set of nearest neighbors. In some implementations, the second set of nearest neighbors can be determined using approximate nearest neighbor methods as described herein. In some implementations, the second set of nearest neighbors can be, for example, 1%, 5%, 10%, 15%, 20%, 30%, or some other percentage of the number of users included in the first set of nearest neighbors. As an example, a set of all users can include about 100 million users, the first set of nearest neighbors can be about 15 million users, and the second set of nearest neighbors can be about 700,000 users. It will be appreciated that these numbers are merely examples, and the actual values can vary depending upon the total number of users, the number of groupings, a minimum and/or maximize size of each grouping, and so forth.

In some implementations, a system can use a word embeddings matrix generator to generate word embeddings based on call transcripts, chat transcripts, text transcripts, email transcripts, in-store interaction summaries, and so forth. In some implementations, some filtering may be applied to the input data prior to determining word embeddings. For example, when determining user intent, it may be advantageous to remove dialog from a support agent, chatbot, etc., so that only the user's input is considered, although in some cases, it may be desirable to retain the full dialog. In some implementations, the system can use a dimensionality reducer, such as an intrinsic dimension transformer, to simplify word embeddings. In some implementations, the system can use a large language model to generate word embeddings, to summarize calls and/or other user interactions, and so forth.

In some implementations, the word embeddings matrix generator can use techniques such as term frequency-inverse document frequency to measure the importance of words in call transcripts, chat transcripts, and so forth. In some implementations, words of low importance can be dropped, which can simplify vectors and/or improve results obtained using such vectors as less important information is removed and thus unable to affect results. In some implementations, the word embeddings matrix generator can generate n-gram vectors. In some implementations, a large language model (LLM) can process transcripts and can provide embeddings, and the word embeddings matrix generator can use the LLM embeddings when generating a word embeddings matrix. For example, the word embeddings matrix generator can include an LLM, and the LLM can be used to process transcripts (e.g., call transcripts, chat transcripts, email transcripts, etc.), for example to generate summaries and/or to output embeddings. In some implementations, LLM embeddings can result in more reliable outputs than some other approaches, for example when there are long transcripts.

In some implementations, the system can use cosine similarity or another similarity metric when determining the first set of nearest neighbors and/or the second set of nearest neighbors. Cosine similarity involves measuring the similarity between two vectors in a vector space. In some implementations, interactions (e.g., calls, texts, chats, emails, etc.) can be represented as vectors (e.g., embeddings). Each dimension of a vector can correspond to a specific feature or characteristic. To determine the similarity between users, the cosine similarity can be calculated. For example, for a first user represented by a vector \vec{A} and a second user represented by a vector \vec{B}, the cosine similarity can be defined as \vec{A}·\vec{B}/(∥\vec{A}||\vec{B}|). The cosine similarity can range from −1 to 1, with 1 indicating identical vectors, 0 indicating no similarity (e.g., the vectors are orthogonal), and −1 representing complete dissimilarity. In some implementations, negative values may not be possible, and the cosine similarity can range from 0 to 1. While cosine similarity is described in detail, it will be appreciated that other metrics can be used. For example, in some implementations, Euclidian distance (also known as L2 distance) can be used. In some implementations, Manhattan distance (also known as L1 distance) can be used. In a Euclidian distance approach, the straight-line distance between points is calculated. In a Manhattan distance approach, the absolute differences along each dimension are added together. In some implementations, rather than computing cosine similarity, the dot product between two vectors can be calculated. It will be appreciated that different similarity approaches may provide better results and/or require fewer computational resources, and a similarity approach can be selected based on a variety of factors such as performance.

By dividing the nearest neighbors determination into two stages, the system can achieve significant performance gains as compared with a single nearest neighbor determination step. For example, the first nearest neighbor determination step can use relatively small, simple attributes vectors on a large dataset. Word embeddings can be much larger, but calculations with word embeddings may only be performed on users that have already been identified as similar based on their attributes.

The second set of nearest neighbors can be provided to a weighted retrieval top generator configured to output top recommended intents and/or treatments based on historical user data. For example, the weighted retrieval top generator can receive as inputs the second set of nearest neighbors, a historical user treatment matrix, and a historical intent matrix. In some implementations, the system can be configured to generate the historical treatment matrix, the historical intent matrix, or both based on user data accessible by the system, such as historical purchases, historical customer service interactions, and so forth. The system can generate, using the weighted top retrieval generator, top recommended intents and/or top recommended treatments based on historical intents and/or historical treatments of similar users. In some implementations, the system can be configured to generate both recommended intents and recommended treatments, but in other implementations, the system can be configured to generate either recommended intents or recommended treatments.

In the preceding description, user attributes, user treatments, user intents, and user word embeddings based on interactions with the company are considered. It will be appreciated that, in some implementations, other data can, additionally or alternatively, be considered by a recommender system. For example, in some implementations, network data can be used when determining recommended intents and/or recommended treatments. For example, if network monitoring data indicates an outage, capacity issue, etc., in a user's location, the system can determine that a top user intent is likely to be to inquire about problems with the network. As another example, if a new service such as HSI has recently been rolled out in the user's location, a recommended treatment can be to offer HSI service to the user.

In some implementations, a recommender system can utilize third party data. For example, in some implementations, the third party data can include census data (e.g., population, income, etc.), credit bureau data, competitor intelligence data (e.g., the performance and/or coverage of other networks in the user's location), flight data (e.g., if a user just booked an international trip, it may be likely that they contact the telecommunications company regarding international roaming or international data).

In some implementations, a recommender system can consider a user's click stream when determining recommended intents and/or recommended treatments. For example, a user may access a wireless telecommunication company's website, mobile application, etc., and may explore services, products, etc. For example, a user can browse the website for a new smartphone but may not complete a checkout process. If the user subsequently calls support, it can be likely that the user is calling to inquire about purchasing a new smartphone. As another example, a user may browse plan add-ons such as international roaming but may not add the service through the website. If the user calls, the recommender system can determine that the intent is likely to be to add international roaming. In some cases, the recommender system can suggest that a support representative suggest adding international roaming as a treatment, as the user has shown some interest in international roaming. While the above examples relate to shopping, it will be appreciated that the user's click stream can also be analyzed to determine that a user is calling about a particular issue, for example if a user searched for a particular issue, viewed particular support documents, and so forth.

### Wireless Communications System

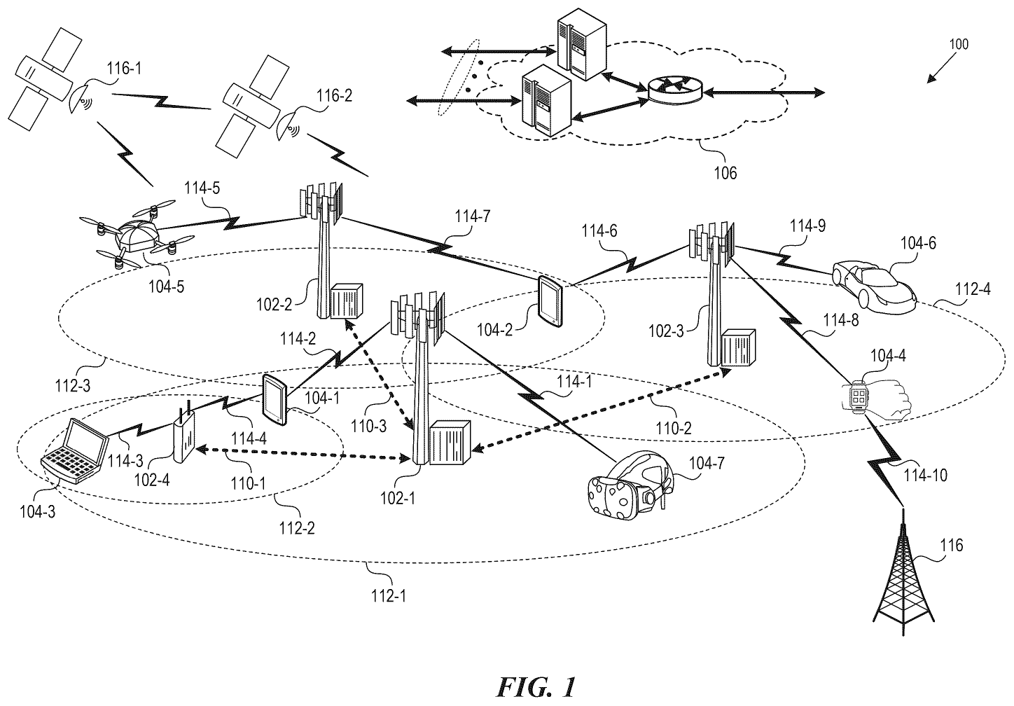

FIG. 1 is a block diagram that illustrates a wireless telecommunication network 100 (“network 100”) in which aspects of the disclosed technology are incorporated. The network 100 includes base stations 102-1 through 102-4 (also referred to individually as “base station 102” or collectively as “base stations 102”). A base station is a type of network access node (NAN) that can also be referred to as a cell site, a base transceiver station, or a radio base station. The network 100 can include any combination of NANs including an access point, radio transceiver, gNodeB (gNB), NodeB, eNodeB (eNB), Home NodeB or Home eNodeB, or the like. In addition to being a wireless wide area network (WWAN) base station, a NAN can be a wireless local area network (WLAN) access point, such as an Institute of Electrical and Electronics Engineers (IEEE) 802.11 access point.

The NANs of a network 100 formed by the network 100 also include wireless devices 104-1 through 104-7 (referred to individually as “wireless device 104” or collectively as “wireless devices 104”) and a core network 106. The wireless devices 104 can correspond to or include network 100 entities capable of communication using various connectivity standards. For example, a 5G communication channel can use millimeter wave (mmW) access frequencies of 28 GHz or more. In some implementations, the wireless device 104 can operatively couple to a base station 102 over a long-term evolution/long-term evolution-advanced (LTE/LTE-A) communication channel, which is referred to as a 4G communication channel.

The core network 106 provides, manages, and controls security services, user authentication, access authorization, tracking, internet protocol (IP) connectivity, and other access, routing, or mobility functions. The base stations 102 interface with the core network 106 through a first set of backhaul links (e.g., S1 interfaces) and can perform radio configuration and scheduling for communication with the wireless devices 104 or can operate under the control of a base station controller (not shown). In some examples, the base stations 102 can communicate with each other, either directly or indirectly (e.g., through the core network 106), over a second set of backhaul links 110-1 through 110-3 (e.g., X1 interfaces), which can be wired or wireless communication links.

The base stations 102 can wirelessly communicate with the wireless devices 104 via one or more base station antennas. The cell sites can provide communication coverage for geographic coverage areas 112-1 through 112-4 (also referred to individually as “coverage area 112” or collectively as “coverage areas 112”). The coverage area 112 for a base station 102 can be divided into sectors making up only a portion of the coverage area (not shown). The network 100 can include base stations of different types (e.g., macro and/or small cell base stations). In some implementations, there can be overlapping coverage areas 112 for different service environments (e.g., Internet of Things (IoT), mobile broadband (MBB), vehicle-to-everything (V2X), machine-to-machine (M2M), machine-to-everything (M2X), ultra-reliable low-latency communication (URLLC), machine-type communication (MTC), etc.).

The network 100 can include a 5G network 100 and/or an LTE/LTE-A or other network. In an LTE/LTE-A network, the term “eNBs” is used to describe the base stations 102, and in 5G new radio (NR) networks, the term “gNBs” is used to describe the base stations 102 that can include mmW communications. The network 100 can thus form a heterogeneous network 100 in which different types of base stations provide coverage for various geographic regions. For example, each base station 102 can provide communication coverage for a macro cell, a small cell, and/or other types of cells. As used herein, the term “cell” can relate to a base station, a carrier or component carrier associated with the base station, or a coverage area (e.g., sector) of a carrier or base station, depending on context.

A macro cell generally covers a relatively large geographic area (e.g., several kilometers in radius) and can allow access by wireless devices that have service subscriptions with a wireless network 100 service provider. As indicated earlier, a small cell is a lower-powered base station, as compared to a macro cell, and can operate in the same or different (e.g., licensed, unlicensed) frequency bands as macro cells. Examples of small cells include pico cells, femto cells, and micro cells. In general, a pico cell can cover a relatively smaller geographic area and can allow unrestricted access by wireless devices that have service subscriptions with the network 100 provider. A femto cell covers a relatively smaller geographic area (e.g., a home) and can provide restricted access by wireless devices having an association with the femto unit (e.g., wireless devices in a closed subscriber group (CSG), wireless devices for users in the home). A base station can support one or multiple (e.g., two, three, four, and the like) cells (e.g., component carriers). All fixed transceivers noted herein that can provide access to the network 100 are NANs, including small cells.

The communication networks that accommodate various disclosed examples can be packet-based networks that operate according to a layered protocol stack. In the user plane, communications at the bearer or Packet Data Convergence Protocol (PDCP) layer can be IP-based. A Radio Link Control (RLC) layer then performs packet segmentation and reassembly to communicate over logical channels. A Medium Access Control (MAC) layer can perform priority handling and multiplexing of logical channels into transport channels. The MAC layer can also use Hybrid ARQ (HARQ) to provide retransmission at the MAC layer, to improve link efficiency. In the control plane, the Radio Resource Control (RRC) protocol layer provides establishment, configuration, and maintenance of an RRC connection between a wireless device 104 and the base stations 102 or core network 106 supporting radio bearers for the user plane data. At the Physical (PHY) layer, the transport channels are mapped to physical channels.

Wireless devices can be integrated with or embedded in other devices. As illustrated, the wireless devices 104 are distributed throughout the network 100, where each wireless device 104 can be stationary or mobile. For example, wireless devices can include handheld mobile devices 104-1 and 104-2 (e.g., smartphones, portable hotspots, tablets, etc.); laptops 104-3; wearables 104-4; drones 104-5; vehicles with wireless connectivity 104-6; head-mounted displays with wireless augmented reality/virtual reality (AR/VR) connectivity 104-7; portable gaming consoles; wireless routers, gateways, modems, and other fixed-wireless access devices; wirelessly connected sensors that provide data to a remote server over a network; IoT devices such as wirelessly connected smart home appliances; etc.

A wireless device (e.g., wireless devices 104) can be referred to as a user equipment (UE), a customer premises equipment (CPE), a mobile station, a subscriber station, a mobile unit, a subscriber unit, a wireless unit, a remote unit, a handheld mobile device, a remote device, a mobile subscriber station, a terminal equipment, an access terminal, a mobile terminal, a wireless terminal, a remote terminal, a handset, a mobile client, a client, or the like.

A wireless device can communicate with various types of base stations and network 100 equipment at the edge of a network 100 including macro eNBs/gNBs, small cell eNBs/gNBs, relay base stations, and the like. A wireless device can also communicate with other wireless devices either within or outside the same coverage area of a base station via device-to-device (D2D) communications.

The communication links 114-1 through 114-9 (also referred to individually as “communication link 114” or collectively as “communication links 114”) shown in network 100 include uplink (UL) transmissions from a wireless device 104 to a base station 102 and/or downlink (DL) transmissions from a base station 102 to a wireless device 104. The downlink transmissions can also be called forward link transmissions while the uplink transmissions can also be called reverse link transmissions. Each communication link 114 includes one or more carriers, where each carrier can be a signal composed of multiple sub-carriers (e.g., waveform signals of different frequencies) modulated according to the various radio technologies. Each modulated signal can be sent on a different sub-carrier and carry control information (e.g., reference signals, control channels), overhead information, user data, etc. The communication links 114 can transmit bidirectional communications using frequency division duplex (FDD) (e.g., using paired spectrum resources) or time division duplex (TDD) operation (e.g., using unpaired spectrum resources). In some implementations, the communication links 114 include LTE and/or mmW communication links.

In some implementations of the network 100, the base stations 102 and/or the wireless devices 104 include multiple antennas for employing antenna diversity schemes to improve communication quality and reliability between base stations 102 and wireless devices 104. Additionally or alternatively, the base stations 102 and/or the wireless devices 104 can employ multiple-input, multiple-output (MIMO) techniques that can take advantage of multi-path environments to transmit multiple spatial layers carrying the same or different coded data.

In some examples, the network 100 implements 6G technologies including increased densification or diversification of network nodes. The network 100 can enable terrestrial and non-terrestrial transmissions. In this context, a Non-Terrestrial Network (NTN) is enabled by one or more satellites, such as satellites 116-1 and 116-2, to deliver services anywhere and anytime and provide coverage in areas that are unreachable by any conventional Terrestrial Network (TN). A 6G implementation of the network 100 can support terahertz (THz) communications. This can support wireless applications that demand ultrahigh quality of service (QoS) requirements and multi-terabits-per-second data transmission in the era of 6G and beyond, such as terabit-per-second backhaul systems, ultra-high-definition content streaming among mobile devices, AR/VR, and wireless high-bandwidth secure communications. In another example of 6G, the network 100 can implement a converged Radio Access Network (RAN) and Core architecture to achieve Control and User Plane Separation (CUPS) and achieve extremely low user plane latency. In yet another example of 6G, the network 100 can implement a converged Wi-Fi and Core architecture to increase and improve indoor coverage.

### 5G Core Network Functions

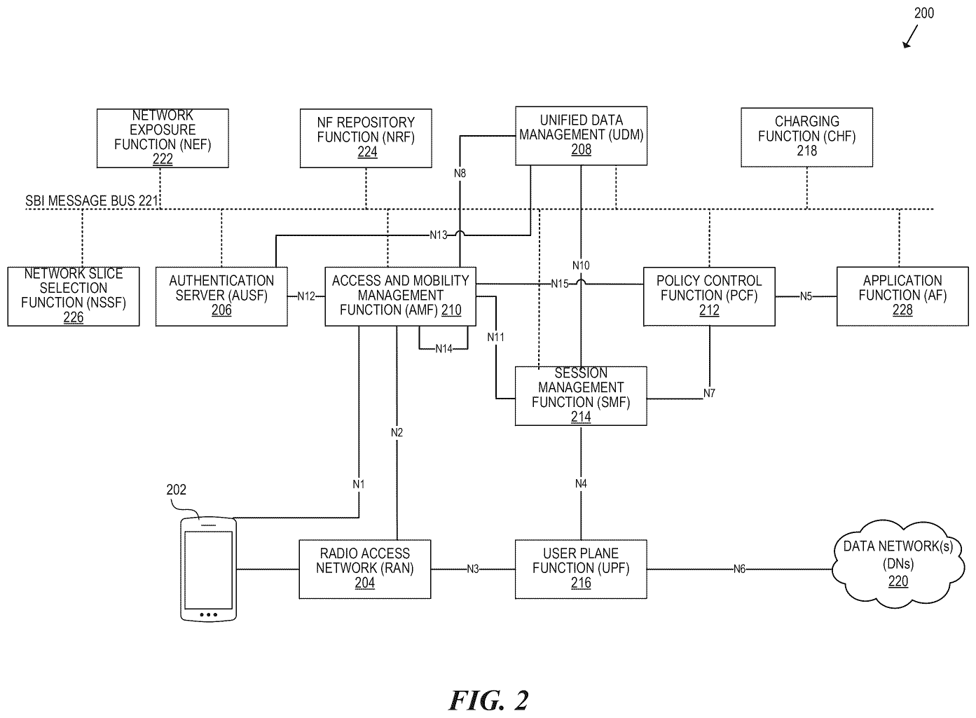

FIG. 2 is a block diagram that illustrates an architecture 200 including 5G core network functions (NFs) that can implement aspects of the present technology. A wireless device 202 can access the 5G network through a NAN (e.g., gNB) of a RAN 204. The NFs include an Authentication Server Function (AUSF) 206, a Unified Data Management (UDM) 208, an Access and Mobility management Function (AMF) 210, a Policy Control Function (PCF) 212, a Session Management Function (SMF) 214, a User Plane Function (UPF) 216, and a Charging Function (CHF) 218.

The interfaces N1 through N15 define communications and/or protocols between each NF as described in relevant standards. The UPF 216 is part of the user plane and the AMF 210, SMF 214, PCF 212, AUSF 206, and UDM 208 are part of the control plane. One or more UPFs can connect with one or more data networks (DNs) 220. The UPF 216 can be deployed separately from control plane functions. The NFs of the control plane are modularized such that they can be scaled independently. As shown, each NF service exposes its functionality in a Service Based Architecture (SBA) through a Service Based Interface (SBI) 221 that uses HTTP/2. The SBA can include a Network Exposure Function (NEF) 222, an NF Repository Function (NRF) 224, a Network Slice Selection Function (NSSF) 226, and other functions such as a Service Communication Proxy (SCP).

The SBA can provide a complete service mesh with service discovery, load balancing, encryption, authentication, and authorization for interservice communications. The SBA employs a centralized discovery framework that leverages the NRF 224, which maintains a record of available NF instances and supported services. The NRF 224 allows other NF instances to subscribe and be notified of registrations from NF instances of a given type. The NRF 224 supports service discovery by receipt of discovery requests from NF instances and, in response, details which NF instances support specific services.

The NSSF 226 enables network slicing, which is a capability of 5G to bring a high degree of deployment flexibility and efficient resource utilization when deploying diverse network services and applications. A logical end-to-end (E2E) network slice has pre-determined capabilities, traffic characteristics, and service-level agreements and includes the virtualized resources required to service the needs of a Mobile Virtual Network Operator (MVNO) or group of subscribers, including a dedicated UPF, SMF, and PCF. The wireless device 202 is associated with one or more network slices, which all use the same AMF. A Single Network Slice Selection Assistance Information (S-NSSAI) function operates to identify a network slice. Slice selection is triggered by the AMF, which receives a wireless device registration request. In response, the AMF retrieves permitted network slices from the UDM 208 and then requests an appropriate network slice of the NSSF 226.

The UDM 208 introduces a User Data Convergence (UDC) that separates a User Data Repository (UDR) for storing and managing subscriber information. As such, the UDM 208 can employ the UDC under 3GPP TS 22.101 to support a layered architecture that separates user data from application logic. The UDM 208 can include a stateful message store to hold information in local memory or can be stateless and store information externally in a database of the UDR. The stored data can include profile data for subscribers and/or other data that can be used for authentication purposes. Given a large number of wireless devices that can connect to a 5G network, the UDM 208 can contain voluminous amounts of data that is accessed for authentication. Thus, the UDM 208 is analogous to a Home Subscriber Server (HSS) and can provide authentication credentials while being employed by the AMF 210 and SMF 214 to retrieve subscriber data and context.

The PCF 212 can connect with one or more Application Functions (AFs) 228. The PCF 212 supports a unified policy framework within the 5G infrastructure for governing network behavior. The PCF 212 accesses the subscription information required to make policy decisions from the UDM 208 and then provides the appropriate policy rules to the control plane functions so that they can enforce them. The SCP (not shown) provides a highly distributed multi-access edge compute cloud environment and a single point of entry for a cluster of NFs once they have been successfully discovered by the NRF 224. This allows the SCP to become the delegated discovery point in a datacenter, offloading the NRF 224 from distributed service meshes that make up a network operator's infrastructure. Together with the NRF 224, the SCP forms the hierarchical 5G service mesh.

The AMF 210 receives requests and handles connection and mobility management while forwarding session management requirements over the N11 interface to the SMF 214. The AMF 210 determines that the SMF 214 is best suited to handle the connection request by querying the NRF 224. That interface and the N11 interface between the AMF 210 and the SMF 214 assigned by the NRF 224 use the SBI 221. During session establishment or modification, the SMF 214 also interacts with the PCF 212 over the N7 interface and the subscriber profile information stored within the UDM 208. Employing the SBI 221, the PCF 212 provides the foundation of the policy framework that, along with the more typical QoS and charging rules, includes network slice selection, which is regulated by the NSSF 226.

### Transformer for Neural Network

To assist in understanding the present disclosure, some concepts relevant to neural networks and machine learning (ML) are discussed herein. Generally, a neural network comprises a number of computation units (sometimes referred to as “neurons”). Each neuron receives an input value and applies a function to the input to generate an output value. The function typically includes a parameter (also referred to as a “weight”) whose value is learned through the process of training. A plurality of neurons may be organized into a neural network layer (or simply “layer”) and there may be multiple such layers in a neural network. The output of one layer may be provided as input to a subsequent layer. Thus, input to a neural network may be processed through a succession of layers until an output of the neural network is generated by a final layer. This is a simplistic discussion of neural networks and there may be more complex neural network designs that include feedback connections, skip connections, and/or other such possible connections between neurons and/or layers, which are not discussed in detail here.

A deep neural network (DNN) is a type of neural network having multiple layers and/or a large number of neurons. The term DNN may encompass any neural network having multiple layers, including convolutional neural networks (CNNs), recurrent neural networks (RNNs), multilayer perceptrons (MLPs), Generative Adversarial Networks (GANs), Variational Autoencoders (VAEs), and Auto-regressive Models, among others.

DNNs are often used as ML-based models for modeling complex behaviors (e.g., human language, image recognition, object classification) in order to improve the accuracy of outputs (e.g., more accurate predictions) such as, for example, as compared with models with fewer layers. In the present disclosure, the term “ML-based model” or more simply “ML model” may be understood to refer to a DNN. Training an ML model refers to a process of learning the values of the parameters (or weights) of the neurons in the layers such that the ML model is able to model the target behavior to a desired degree of accuracy. Training typically requires the use of a training dataset, which is a set of data that is relevant to the target behavior of the ML model.

As an example, to train an ML model that is intended to model human language (also referred to as a language model), the training dataset may be a collection of text documents, referred to as a text corpus (or simply referred to as a corpus). The corpus may represent a language domain (e.g., a single language), a subject domain (e.g., scientific papers), and/or may encompass another domain or domains, be they larger or smaller than a single language or subject domain. For example, a relatively large, multilingual, and non-subject-specific corpus may be created by extracting text from online webpages and/or publicly available social media posts. Training data may be annotated with ground truth labels (e.g., each data entry in the training dataset may be paired with a label), or training data may be unlabeled.

Training an ML model generally involves inputting into an ML model (e.g., an untrained ML model) training data to be processed by the ML model, processing the training data using the ML model, collecting the output generated by the ML model (e.g., based on the inputted training data), and comparing the output to a desired set of target values. If the training data is labeled, the desired target values may be, e.g., the ground truth labels of the training data. If the training data is unlabeled, the desired target value may be a reconstructed (or otherwise processed) version of the corresponding ML model input (e.g., in the case of an autoencoder), or can be a measure of some target observable effect on the environment (e.g., in the case of a reinforcement learning agent). The parameters of the ML model are updated based on a difference between the generated output value and the desired target value. For example, if the value outputted by the ML model is excessively high, the parameters may be adjusted so as to lower the output value in future training iterations. An objective function is a way to quantitatively represent how close the output value is to the target value. An objective function represents a quantity (or one or more quantities) to be optimized (e.g., minimize a loss or maximize a reward) in order to bring the output value as close to the target value as possible. The goal of training the ML model typically is to minimize a loss function or maximize a reward function.

The training data may be a subset of a larger data set. For example, a data set may be split into three mutually exclusive subsets: a training set, a validation (or cross-validation) set, and a testing set. The three subsets of data may be used sequentially during ML model training. For example, the training set may be first used to train one or more ML models, each ML model, e.g., having a particular architecture, having a particular training procedure, being describable by a set of model hyperparameters, and/or otherwise being varied from the other of the one or more ML models. The validation (or cross-validation) set may then be used as input data into the trained ML models to, e.g., measure the performance of the trained ML models and/or compare performance between them. Where hyperparameters are used, a new set of hyperparameters may be determined based on the measured performance of one or more of the trained ML models, and the first step of training (i.e., with the training set) may begin again on a different ML model described by the new set of determined hyperparameters. In this way, these steps may be repeated to produce a more performant trained ML model. Once such a trained ML model is obtained (e.g., after the hyperparameters have been adjusted to achieve a desired level of performance), a third step of collecting the output generated by the trained ML model applied to the third subset (the testing set) may begin. The output generated from the testing set may be compared with the corresponding desired target values to give a final assessment of the trained ML model's accuracy. Other segmentations of the larger data set and/or schemes for using the segments for training one or more ML models are possible.

Backpropagation is an algorithm for training an ML model. Backpropagation is used to adjust (also referred to as update) the value of the parameters in the ML model, with the goal of optimizing the objective function. For example, a defined loss function is calculated by forward propagation of an input to obtain an output of the ML model and a comparison of the output value with the target value. Backpropagation calculates a gradient of the loss function with respect to the parameters of the ML model, and a gradient algorithm (e.g., gradient descent) is used to update (i.e., “learn”) the parameters to reduce the loss function. Backpropagation is performed iteratively so that the loss function is converged or minimized. Other techniques for learning the parameters of the ML model may be used. The process of updating (or learning) the parameters over many iterations is referred to as training. Training may be carried out iteratively until a convergence condition is met (e.g., a predefined maximum number of iterations has been performed, or the value outputted by the ML model is sufficiently converged with the desired target value), after which the ML model is considered to be sufficiently trained. The values of the learned parameters may then be fixed, and the ML model may be deployed to generate output in real-world applications (also referred to as “inference”).

In some examples, a an LLM model or transformer-based model may be fine-tuned, meaning that the values of the learned parameters may be adjusted slightly in order for the model to better model a specific task. Fine-tuning of a model typically involves further training the model on a number of data samples (which may be smaller in number/cardinality than those used to train the model initially) that closely target the specific task. For example, a model for generating natural language that has been trained generically on publicly-available text corpora may be, e.g., fine-tuned by further training using specific training samples. The specific training samples can be used to generate language in a certain style or in a certain format. For example, the model can be trained to generate a blog post having a particular style and structure with a given topic.

Some concepts in ML-based language models are now discussed. It may be noted that, while the term “language model” has been commonly used to refer to a ML-based language model, there could exist non-ML language models. In the present disclosure, the term “language model” may be used as shorthand for an ML-based language model (i.e., a language model that is implemented using a neural network, transformers, or other ML architecture), unless stated otherwise. For example, unless stated otherwise, the “language model” encompasses LLMs.

A language model may use a neural network (typically a DNN) to perform natural language processing (NLP) tasks. A language model may be trained to model how words relate to each other in a textual sequence, based on probabilities. A language model may contain hundreds of thousands of learned parameters or in the case of a large language model (LLM) may contain millions or billions of learned parameters or more. As non-limiting examples, a language model can generate text, translate text, summarize text, answer questions, write code (e.g., Phyton, JavaScript, or other programming languages), classify text (e.g., to identify spam emails), create content for various purposes (e.g., social media content, factual content, or marketing content), or create personalized content for a particular individual or group of individuals. Language models can also be used for chatbots (e.g., virtual assistance).

In recent years, there has been interest in a type of neural network architecture, referred to as a transformer, for use as language models. For example, the Bidirectional Encoder Representations from Transformers (BERT) model, the Transformer-XL model, and the Generative Pre-trained Transformer (GPT) models are types of transformers. A transformer is a type of neural network architecture that uses self-attention mechanisms in order to generate predicted output based on input data that has some sequential meaning (i.e., the order of the input data is meaningful, which is the case for most text input). Although transformer-based language models are described herein, it should be understood that the present disclosure may be applicable to any ML-based language model, including language models based on other neural network architectures such as recurrent neural network (RNN)-based language models.

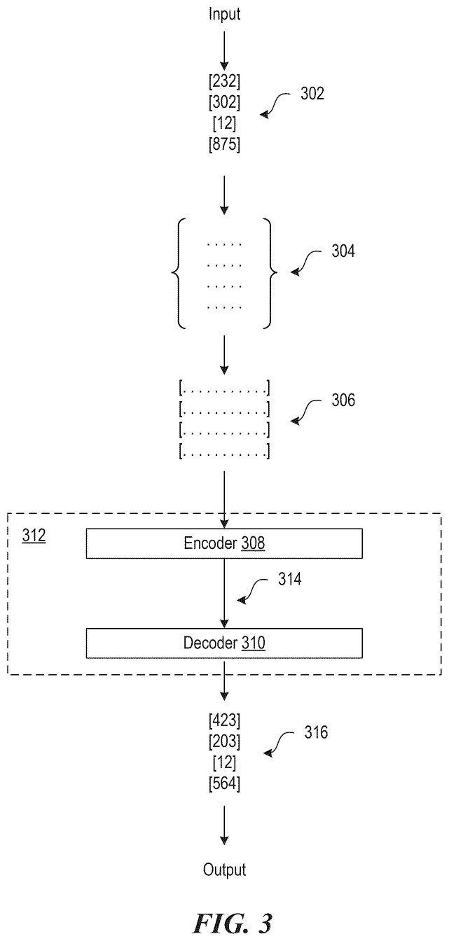

FIG. 3 is a block diagram of an example transformer 312. A transformer is a type of neural network architecture that uses self-attention mechanisms to generate predicted output based on input data that has some sequential meaning (i.e., the order of the input data is meaningful, which is the case for most text input). Self-attention is a mechanism that relates different positions of a single sequence to compute a representation of the same sequence. Although transformer-based language models are described herein, it should be understood that the present disclosure may be applicable to any machine learning (ML)-based language model, including language models based on other neural network architectures such as recurrent neural network (RNN)-based language models.

The transformer 312 includes an encoder 308 (which can comprise one or more encoder layers/blocks connected in series) and a decoder 310 (which can comprise one or more decoder layers/blocks connected in series). Generally, the encoder 308 and the decoder 310 each include a plurality of neural network layers, at least one of which can be a self-attention layer. The parameters of the neural network layers can be referred to as the parameters of the language model.

The transformer 312 can be trained to perform certain functions on a natural language input. For example, the functions include summarizing existing content, brainstorming ideas, writing a rough draft, fixing spelling and grammar, and translating content. Summarizing can include extracting key points from an existing content in a high-level summary. Brainstorming ideas can include generating a list of ideas based on provided input. For example, the ML model can generate a list of names for a startup or costumes for an upcoming party. Writing a rough draft can include generating writing in a particular style that could be useful as a starting point for the user's writing. The style can be identified as, e.g., an email, a blog post, a social media post, or a poem. Fixing spelling and grammar can include correcting errors in an existing input text. Translating can include converting an existing input text into a variety of different languages. In some embodiments, the transformer 312 is trained to perform certain functions on other input formats than natural language input. For example, the input can include objects, images, audio content, or video content, or a combination thereof.

The transformer 312 can be trained on a text corpus that is labeled (e.g., annotated to indicate verbs, nouns) or unlabeled. Large language models (LLMs) can be trained on a large unlabeled corpus. The term “language model,” as used herein, can include an ML-based language model (e.g., a language model that is implemented using a neural network or other ML architecture), unless stated otherwise. Some LLMs can be trained on a large multi-language, multi-domain corpus to enable the model to be versatile at a variety of language-based tasks such as generative tasks (e.g., generating human-like natural language responses to natural language input). FIG. 3 illustrates an example of how the transformer 312 can process textual input data. Input to a language model (whether transformer-based or otherwise) typically is in the form of natural language that can be parsed into tokens. It should be appreciated that the term “token” in the context of language models and Natural Language Processing (NLP) has a different meaning from the use of the same term in other contexts such as data security. Tokenization, in the context of language models and NLP, refers to the process of parsing textual input (e.g., a character, a word, a phrase, a sentence, a paragraph) into a sequence of shorter segments that are converted to numerical representations referred to as tokens (or “compute tokens”). Typically, a token can be an integer that corresponds to the index of a text segment (e.g., a word) in a vocabulary dataset. Often, the vocabulary dataset is arranged by frequency of use. Commonly occurring text, such as punctuation, can have a lower vocabulary index in the dataset and thus be represented by a token having a smaller integer value than less commonly occurring text. Tokens frequently correspond to words, with or without white space appended. In some examples, a token can correspond to a portion of a word.

For example, the word “greater” can be represented by a token for [great] and a second token for [er]. In another example, the text sequence “write a summary” can be parsed into the segments [write], [a], and [summary], each of which can be represented by a respective numerical token. In addition to tokens that are parsed from the textual sequence (e.g., tokens that correspond to words and punctuation), there can also be special tokens to encode non-textual information. For example, a [CLASS] token can be a special token that corresponds to a classification of the textual sequence (e.g., can classify the textual sequence as a list, a paragraph), an [EOT] token can be another special token that indicates the end of the textual sequence, other tokens can provide formatting information, etc.

In FIG. 3, a short sequence of tokens 302 corresponding to the input text is illustrated as input to the transformer 312. Tokenization of the text sequence into the tokens 302 can be performed by some pre-processing tokenization module such as, for example, a byte-pair encoding tokenizer (the “pre” referring to the tokenization occurring prior to the processing of the tokenized input by the LLM), which is not shown in FIG. 3 for simplicity. In general, the token sequence that is inputted to the transformer 312 can be of any length up to a maximum length defined based on the dimensions of the transformer 312. Each token 302 in the token sequence is converted into an embedding vector 306 (also referred to simply as an embedding 306). An embedding 306 is a learned numerical representation (such as, for example, a vector) of a token that captures some semantic meaning of the text segment represented by the token 302. The embedding 306 represents the text segment corresponding to the token 302 in a way such that embeddings corresponding to semantically related text are closer to each other in a vector space than embeddings corresponding to semantically unrelated text. For example, assuming that the words “write,” “a,” and “summary” each correspond to, respectively, a “write” token, an “a” token, and a “summary” token when tokenized, the embedding 306 corresponding to the “write” token will be closer to another embedding corresponding to the “jot down” token in the vector space as compared to the distance between the embedding 306 corresponding to the “write” token and another embedding corresponding to the “summary” token.

The vector space can be defined by the dimensions and values of the embedding vectors. Various techniques can be used to convert a token 302 to an embedding 306. For example, another trained ML model can be used to convert the token 302 into an embedding 306. In particular, another trained ML model can be used to convert the token 302 into an embedding 306 in a way that encodes additional information into the embedding 306 (e.g., a trained ML model can encode positional information about the position of the token 302 in the text sequence into the embedding 306). In some examples, the numerical value of the token 302 can be used to look up the corresponding embedding in an embedding matrix 304 (which can be learned during training of the transformer 312).

The generated embeddings 306 are input into the encoder 308. The encoder 308 serves to encode the embeddings 306 into feature vectors 314 that represent the latent features of the embeddings 306. The encoder 308 can encode positional information (i.e., information about the sequence of the input) in the feature vectors 314. The feature vectors 314 can have very high dimensionality (e.g., on the order of thousands or tens of thousands), with each element in a feature vector 314 corresponding to a respective feature. The numerical weight of each element in a feature vector 314 represents the importance of the corresponding feature. The space of all possible feature vectors 314 that can be generated by the encoder 308 can be referred to as the latent space or feature space.

Conceptually, the decoder 310 is designed to map the features represented by the feature vectors 314 into meaningful output, which can depend on the task that was assigned to the transformer 312. For example, if the transformer 312 is used for a translation task, the decoder 310 can map the feature vectors 314 into text output in a target language different from the language of the original tokens 302. Generally, in a generative language model, the decoder 310 serves to decode the feature vectors 314 into a sequence of tokens. The decoder 310 can generate output tokens 316 one by one. Each output token 316 can be fed back as input to the decoder 310 in order to generate the next output token 316. By feeding back the generated output and applying self-attention, the decoder 310 is able to generate a sequence of output tokens 316 that has sequential meaning (e.g., the resulting output text sequence is understandable as a sentence and obeys grammatical rules). The decoder 310 can generate output tokens 316 until a special [EOT] token (indicating the end of the text) is generated. The resulting sequence of output tokens 316 can then be converted to a text sequence in post-processing. For example, each output token 316 can be an integer number that corresponds to a vocabulary index. By looking up the text segment using the vocabulary index, the text segment corresponding to each output token 316 can be retrieved, the text segments can be concatenated together, and the final output text sequence can be obtained.

In some examples, the input provided to the transformer 312 includes instructions to perform a function on an existing text. In some examples, the input provided to the transformer includes instructions to perform a function on an existing text. The output can include, for example, a modified version of the input text and instructions to modify the text. The modification can include summarizing, translating, correcting grammar or spelling, changing the style of the input text, lengthening or shortening the text, or changing the format of the text. For example, the input can include the question “What is the weather like in Australia?” and the output can include a description of the weather in Australia.

Although a general transformer architecture for a language model and its theory of operation have been described above, this is not intended to be limiting. Existing language models include language models that are based only on the encoder of the transformer or only on the decoder of the transformer. An encoder-only language model encodes the input text sequence into feature vectors that can then be further processed by a task-specific layer (e.g., a classification layer). BERT is an example of a language model that can be considered to be an encoder-only language model. A decoder-only language model accepts embeddings as input and can use auto-regression to generate an output text sequence. Transformer-XL and GPT-type models can be language models that are considered to be decoder-only language models.

Because GPT-type language models tend to have a large number of parameters, these language models can be considered LLMs. An example of a GPT-type LLM is GPT-3. GPT-3 is a type of GPT language model that has been trained (in an unsupervised manner) on a large corpus derived from documents available to the public online. GPT-3 has a very large number of learned parameters (on the order of hundreds of billions), is able to accept a large number of tokens as input (e.g., up to 2,048 input tokens), and is able to generate a large number of tokens as output (e.g., up to 2,048 tokens). GPT-3 has been trained as a generative model, meaning that it can process input text sequences to predictively generate a meaningful output text sequence. ChatGPT is built on top of a GPT-type LLM and has been fine-tuned with training datasets based on text-based chats (e.g., chatbot conversations). ChatGPT is designed for processing natural language, receiving chat-like inputs, and generating chat-like outputs.

A computer system can access a remote language model (e.g., a cloud-based language model), such as ChatGPT or GPT-3, via a software interface (e.g., an API). Additionally or alternatively, such a remote language model can be accessed via a network such as, for example, the Internet. In some implementations, such as, for example, potentially in the case of a cloud-based language model, a remote language model can be hosted by a computer system that can include a plurality of cooperating (e.g., cooperating via a network) computer systems that can be in, for example, a distributed arrangement. Notably, a remote language model can employ a plurality of processors (e.g., hardware processors such as, for example, processors of cooperating computer systems). Indeed, processing of inputs by an LLM can be computationally expensive/can involve a large number of operations (e.g., many instructions can be executed/large data structures can be accessed from memory), and providing output in a required timeframe (e.g., real time or near real time) can require the use of a plurality of processors/cooperating computing devices as discussed above.

Inputs to an LLM can be referred to as a prompt, which is a natural language input that includes instructions to the LLM to generate a desired output. A computer system can generate a prompt that is provided as input to the LLM via its API. As described above, the prompt can optionally be processed or pre-processed into a token sequence prior to being provided as input to the LLM via its API. A prompt can include one or more examples of the desired output, which provides the LLM with additional information to enable the LLM to generate output according to the desired output. Additionally or alternatively, the examples included in a prompt can provide inputs (e.g., example inputs) corresponding to/as can be expected to result in the desired outputs provided. A one-shot prompt refers to a prompt that includes one example, and a few-shot prompt refers to a prompt that includes multiple examples. A prompt that includes no examples can be referred to as a zero-shot prompt.

### Context-Aware, User-Based Collaborative Filtering Recommender System

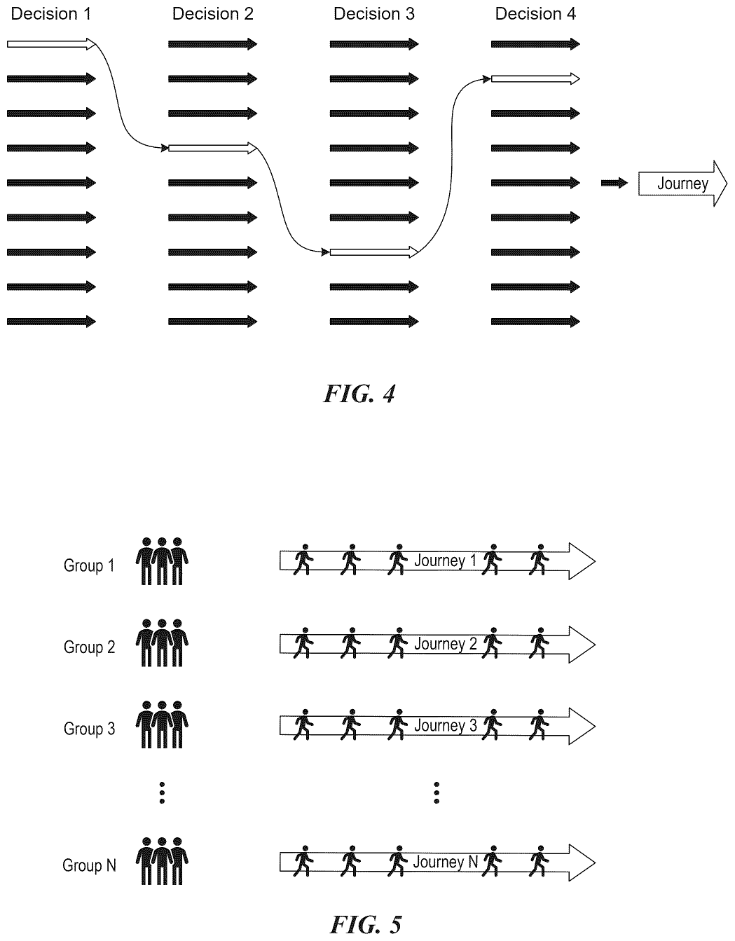

FIG. 4 is a diagram that illustrates a journey according to some implementations. As shown in FIG. 4, various decisions can be made throughout a user's journey (e.g., billing inquiries, troubleshooting inquiries, adding services, removing services, replacing devices, and so forth). In FIG. 4, a first selection is made at decision one from a plurality of possible selections. The selection can indicate a user intent or user treatment. Similarly, second, third, and fourth selections can be made at decisions two, three, and four. The overall decision path can form a user journey. While four decisions are illustrated in FIG. 4, it will be appreciated that there can be many decisions or fewer decisions. For example, a new user may have limited decisions, while a long-term user may have dozens, hundreds, or even thousands of decisions along their journey. In some implementations, a journey can cover up to, for example, a month or about a month, six months or about six months, a year or about a year, two years or about two years, three years or about three years, four years or about four years, five years about five years, or longer.

FIG. 5 is a diagram that shows grouping of users according to their journeys. As discussed above, while each user's journey can be different, in many cases, similar users follow similar journeys. Individual user journeys can be compared as described herein and similar journeys can be grouped together. In FIG. 5, Group 1 represents a group of users associated with Journey 1, Group 2 represents a group of users associated with Journey 2, Group 3 represents a group of users associated with Journey 3, and group N represents a group of users associated with Journey N. In general, the number of journeys N is not limited. A larger number of journeys may offer better insight into users as the similarity of users within a particular group can be greater. However, higher numbers of journeys can also mean that fewer users are on a given journey, which can lead to noise or uncertainty about the journey. For example, a journey that is associated with only a small number of users can be more likely to reflect specific user behaviors of the users in that small group, rather than providing a generally applicable picture of journeys taken by similar users.

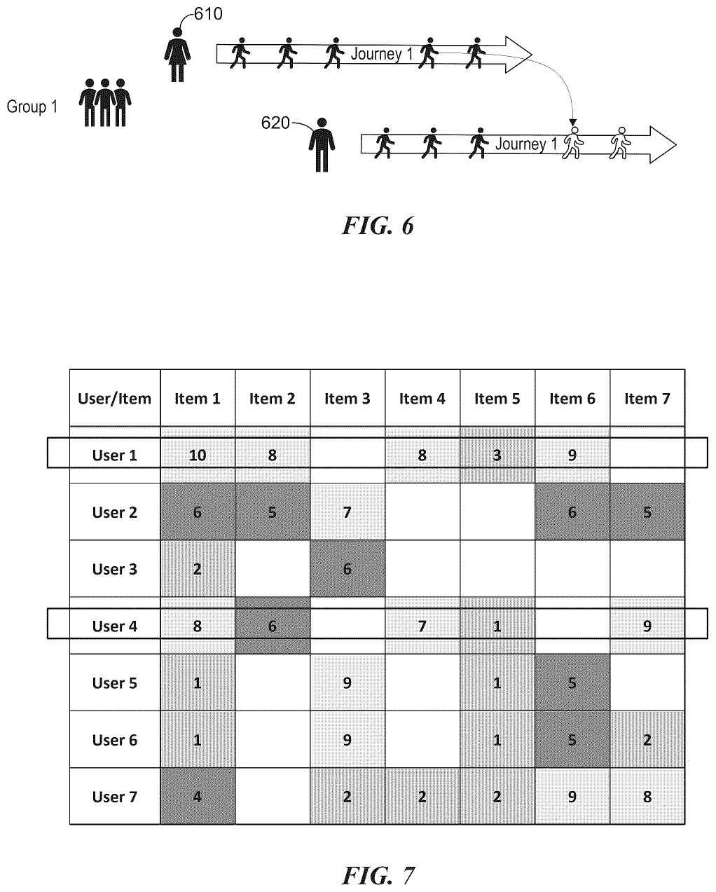

FIG. 6 is a diagram that shows the application of the journey concept according to an implementation. A first user 610 and a second user 620 can be in the same group (e.g., both are on the same journey). The first user 610 can be further along in the journey than the second user 620. Based on the journey followed by the first user 610, the next actions for the second user 620 can be predicted. For example, as shown in FIG. 6, it can be predicted that the fourth step on the journey for the second user 620 will be the same as the fourth step for the first user 610. In some implementations, the fifth step for the second user 620 can also be predicted. The number of steps that can be predicted is not necessarily limited, although it will be appreciated that predicted steps may become less reliable as they are predicted further out from the current step of the user. It will be appreciated that, in practice, the journey of the second user 620 may not be exactly the same as the journey of the first user 610, and the journey of the first user 610 may not be exactly the same as the journey of everyone in Group 1. Rather, the Journey 1 can represent a most likely path followed by the members of Group 1. In some implementations, a journey may not be only a most likely path, but can include probabilities for multiple intents and/or treatments at each step of the journey.

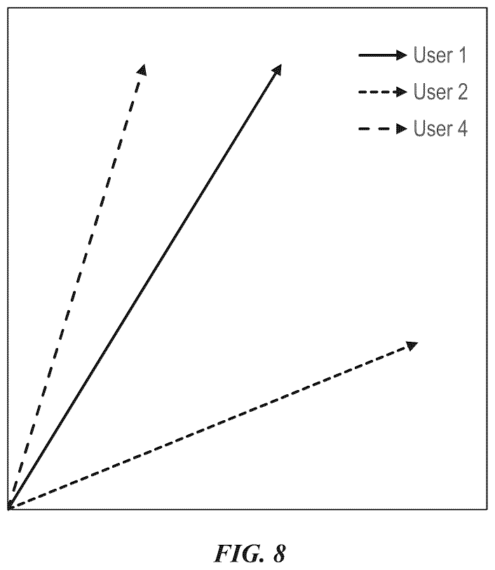

Accurately grouping users into journeys can be important. In some implementations, users within a group can have similar attributes, can follow similar paths, and so forth. Thus, it can be important to identify similar users. FIG. 7 shows a table of various users and various items. The values in the table can indicate, for example, how users ranked the various items. Not all users may have rated all items. Moreover, different users may have a different baseline rating for the items. For example, one user may tend to give lower rankings than another user. For example, if the items are foods, a first user may rate their favorite food as an 8 while another user may rate their favorite food a 10. The ratings of the users can be compared to determine which users are most similar to one another. In FIG. 7, User 1 and User 7 tend to rank the same items similarly (though user 7 tends to give lower ratings in general). In some implementations, each user's ratings of the items can be vectorized, and the vectors can be compared to determine similarity. For example, cosine similarity can be used to compare the vectors. Other approaches may also be used, such as Manhattan distance, Euclidian distance, dot product, and so forth, as described herein.

FIG. 8 is a plot that shows a graphical depiction of vectorized representations of the rankings in FIG. 4. Only three users are depicted in FIG. 8, but it will be appreciated that all users can be included in the plot. As shown in FIG. 8, the angle between the vector corresponding to user 1 and the vector corresponding to user 4 is smaller than the angle between user 1 and user 2, or between user 2 and user 4. Thus, using a metric such as cosine similarity, it can be determined that user 1 and user 4 are more similar to each other than either is to user 2. In some implementations of the recommender system described herein, user 1 and user 4 can be part of the same group that is on the same journey, because they are similar, even though there are some differences (e.g., they assigned different rankings and did not rank the same items, as shown in FIG. 7).

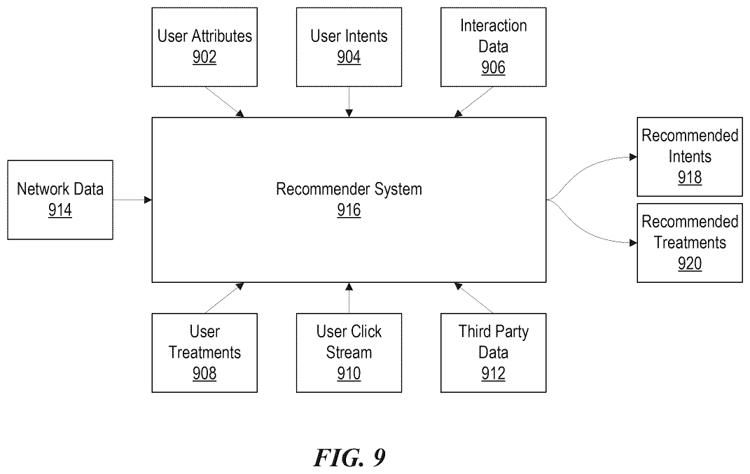

FIG. 9 schematically illustrates a recommender system according to some implementations. As shown in FIG. 9, a recommender system 916 can receive various types of input data. For example, in some implementations, the recommender system 916 can receive user attributes data 902, user intents data 904, interaction data 906, user treatments data 908, user click stream data 910, third party data 912, and/or network data 914. Using the received data, the recommender system 916 can determine similarity between users and can output, for example, recommended intents 918 and/or recommended treatments 920. As described herein, the recommended intents can be likely reasons the user is initiates an interaction with the company, and recommended treatments can include suggestions such as product offerings, discounts, etc., that can be offered to the user, for example to entice the user to remain with the company, make a purchase from the company, sign up for additional services, and so forth.

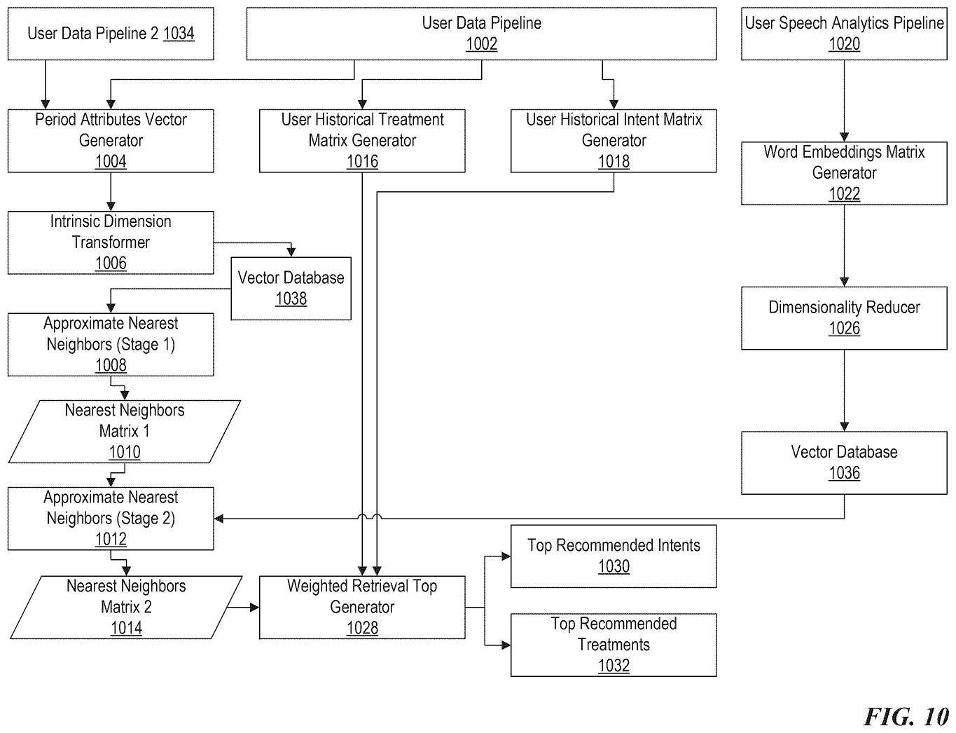

FIG. 10 is a block diagram that illustrates an example system and outputs according to some implementations. A user data pipeline 1002 can provide user attribute data to a period attributes vector generator 1004, a user historical treatment matrix generator 1016, and a user historical intent matrix generator 1018. A user speech analytics pipeline 1020 can provide interaction data (e.g., voice call data, chat transcript data, email data, and/or in-person support data) to a word embeddings matrix generator 1022. The interaction can include, for example, transcripts and/or summaries of interactions. The user historical treatment matrix generator 1016 can use the data received from the user data pipeline 1002 to generate a matrix of historical user treatments (e.g., promotions, sales offers, etc.). The user historical treatment matrix generator 1016 can accept one or more matrices as inputs. For example, the user historical treatment matrix generator 1016 can accept a total users matrix and a treatments matrix, and can use the matrices to generate a historical user treatments matrix. The user historical intent matrix generator 1018 can accept one or more matrices as inputs. For example, the user historical intent matrix generator 1018 can accept the total users matrix and an intents matrix. The user historical intent matrix generator 1018 can use the matrices to generate a historical user intents matrix. The historical user intents matrix can indicate which intents applied to which users over one or more periods.

In some implementations the user historical treatment matrix generator 1016 may not accept matrices as inputs. For example, the user historical treatment matrix generator 1016 can instead retrieve or receive data from the user data pipeline 1002 and generate a user historical treatments matrix based on the data from the user data pipeline 1002. In some implementations, the generated historical treatments matrix can include a plurality of rows and columns, wherein each row represents a user and the columns represent sequences of treatments for each user. In some implementations, the generated historical treatments matrix columns can be padded to a maximum number of treatments that occurred during a defined period or number of periods.

In some implementations, the user historical intent matrix generator 1018 may not accept matrices as inputs. For example, the user historical intent matrix generator 1018 can instead retrieve or receive data from the user data pipeline 1002 and generate a user historical intents matrix based on the data from the user data pipeline 1002. In some implementations, the generated historical intents matrix can include a plurality of rows and columns, wherein each row represents a user and the columns represent sequences of intents for each user. In some implementations, the generated historical intents matrix columns can be padded to a maximum number of intents that occurred during a defined period or number of periods.

The period attributes vector generator 1004 can generate vectors that describe the periodic attributes of users, such as time with a service, number of lines, bill, delinquency status, amount of data usage, amount of roaming usage, international roaming, dropped call rate, download speed, upload speed, age, credit score, income, and so forth. In some implementations, the user data pipeline 1002 can provide information maintained by the telecommunications company. In some implementations, the user data pipeline 1002 can, additionally or alternatively, provide information from one or more third parties. For example, in some implementations, the user data pipeline 1002 can provide information from credit reporting services, census data (e.g., population, population density, median income, etc.), travel data (e.g., flight bookings), and so forth. The period attributes vector generator 1004 can accept one or more matrices and a period parameter as inputs. For example, the period attributes vector generator 1004 can accept a total users matrix, a user attributes matrix, and a number of time periods to be modeled.

In some implementations, a second user data pipeline 1034 can, additionally or alternatively, provide other data to the period attributes vector generator 1004, and the period attributes vector generator 1004 can use data from the second user data pipeline 1034 when generating period attributes vectors. The second user data pipeline 1034 can provide, for example, clickstream data, third party data (e.g., data from credit bureaus, data from third party partnerships (e.g., in-flight Wi-Fi, subscription services, etc.)), and so forth.

The system can provide the period attributes vectors to an intrinsic dimension transformer 1006. The intrinsic dimension transformer 1006 can transform the period attributes vectors to reduce the dimensionality of the period attributes vectors or to otherwise simplify the period attributes vectors. The intrinsic dimension transformer 1006 can, for example, perform principal components analysis on the vectors. In some cases, there can be some loss of information when applying the intrinsic dimension transformer 1006. However, the intrinsic dimension transformer 1006 can enable significantly faster processing in subsequent steps without unacceptable loss of fidelity.

In some implementations, period attributes vectors can be clustered prior to the period attributes vectors being provided to the intrinsic dimension transformer 1006, and the system may provide only a subset of the period attributes vectors to the intrinsic dimension former. For example, the system can provide one or more of the clusters to the intrinsic dimension transformer 1006.

As described herein, there can be a large number of users (e.g., millions). Thus, to maintain overall performance of the system, it can be significant to identify similar users and to perform further processing only on users that appear similar to each other based on user attribute data. In some implementations, the system can provide the output of the intrinsic dimension transformer 1006 to an approximate nearest neighbors algorithm 1008. For example, in some implementations, the system can store the output of the intrinsic dimension transformer 1006 in a vector database 1038, and the algorithm 1008 can access the vector database 1038 to retrieve the vectors. The approximate nearest neighbors algorithm can use approaches such as cosine similarity, dot product, Hamming distance, Manhattan distance, Euclidian distance, and so forth to identify similar vectors. Approximate nearest neighbors algorithms, such as ANNOY, can offer several advantages. While they may not perfectly identify nearest neighbors, they can offer improved performance over other nearest neighbors algorithms while still providing useful output. Notably, some approximate nearest neighbors algorithms perform better when the number of dimensions is relatively small (e.g., about 100 or less). Thus, the use of the intrinsic dimension transformer 1006 prior to identifying nearest neighbors can be significant for improving the performance and results of the approximate nearest neighbors algorithm 1008.

The approximate nearest neighbors algorithm 1008 can output a first nearest neighbors matrix 1010, which can include a reduced number of users (e.g., the most similar 100 users, 1000 users, 10,000 users, 100,000 users, 1,000,000 users, 10,000,000 users, etc.). A second approximate nearest neighbors algorithm 1012 can be applied to the first nearest neighbors matrix 1010 and to a word embeddings matrix generated by the word embeddings matrix generator 1022. In some implementations, the word embeddings can be simplified using a dimensionality reducer 1026, which can, for example, perform principal components analysis, drop some terms from the vectors, and so forth. In some embodiments, word embeddings and/or reduced word embeddings (e.g., word embeddings that have been processed by the dimensionality reducer 1026) can be stored in a vector database 1036.

The second approximate nearest neighbors algorithm can be the same algorithm as the approximate nearest neighbors algorithm 1008 or can be different. The second approximate nearest neighbors algorithm 1012 can output a second nearest neighbors matrix 1014. The second nearest neighbors matrix 1014 can include only those users identified as having similar attributes and similar word embeddings.

The system can provide the second nearest neighbors matrix 1014, the user historical treatment matrix generator 1016, and the user historical intent matrix generator 1018 to a weighted retrieval top generator 1028. The weighted retrieval top generator 1028 can be configured to output one or more top recommended intents 1030. The weighted retrieval top generator 1028 can be configured to output one or more top recommended treatments 1032. In some implementations top recommended intents 1030 and/or top recommended treatments 1032 can be vector outputs. The vector outputs can indicate the most likely next event (e.g., intent or treatment), the following most likely event, and so forth, and each event can have a probability associated therewith. For example, a vector can indicate that next event is most likely A, and if not A then B, and if not B then C, and so forth. The vector can indicate that the following event (e.g., the event after the next event) is most like X, and if not X then Y, and if not Y then Z. The number of next events included in the vector is not necessarily limited and can include, for example, the next one event, two events, three events, four events, five events, ten events, twenty events, or any other number of events.

In FIG. 10, both treatments and intents are considered. However, it will be appreciated that, in some implementations, only intents or only treatments may be considered, and only recommended treatments or recommended intents may be output. Additionally, while, in FIG. 10, only user attributes and word embeddings are used to determine nearest neighbors, it will be appreciated that in some implementations, other data can, additionally or alternatively, be used to identify nearest neighbors. For example, network information (e.g., speed, outages, capacity, etc.), third party data, and so forth can be used to identify nearest neighbors.

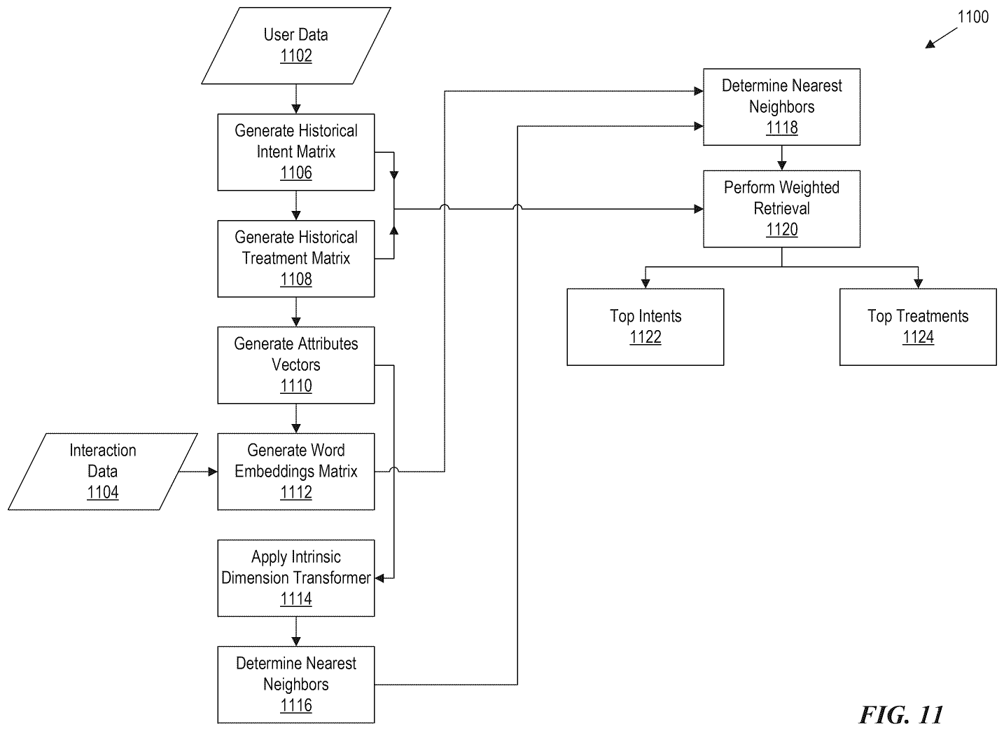

FIG. 11 is a flowchart that illustrates an example process for determining top intents and top treatments according to some implementations. The process 1100 can be performed on a computer system. The operation can accept as inputs user data 1102 and interaction data 1104. The user data 1102 can include user attribute data. The interaction data 1104 can include transcripts of calls, chat transcripts, email transcripts, in-store support records, and so forth. At operation 1106, the system can generate a historical intent matrix using the user data 1102. At operation 1108, the system can generate a historical treatment matrix using the user data 1102. At operation 1110, the system can generate attributes vectors that represent attributes of the users included in the user data 1102. In some implementations, the attributes vectors can be period attributes vectors (e.g., covering a specified date range, a specified number of user interactions, etc.) At operation 1112, the system can generate a word embeddings matrix from the interaction data 1104. The word embeddings matrix can include a matrix representation of common issues, terms, sentiments, and so forth. At operation 1114, the system can apply an intrinsic dimension transformer to the attributes vectors generated at operation 1110. The intrinsic dimension transformer can be used to simplify the vectors. At operation 1116, the system can determine nearest neighbors using the transformed vectors. For example, the system can determine the nearest 10, 100, 1000, 10,000, etc. neighbors. In some implementations, the system can use an approximate nearest neighbor algorithm at operation 1116. At operation 1118, the system can perform a second nearest neighbor determination. At operation 1118, nearest neighbors may only be determined for users that were previously determined to be nearest neighbors based on their attributes. At operation 1118, the nearest neighbors can be determined based on word embeddings matrix generated at operation 1112 and the nearest neighbors determined at operation 1116. In some implementations, the system can use an approximate nearest neighbor algorithm at operation 1118 to determine nearest neighbors. At operation 1120, the system can perform weighted retrieval to output top intents 1122 and top treatments 1124. As described above with respect to FIG. 10, in some implementations, the method may determine either intents or treatments, but not both. In the case that only intents are determined, operation 1108 can be skipped and the historical treatment matrix may not be generated. In the case that only treatments are determined, operation 1106 can be skipped and the historical intents matrix may not be generated.

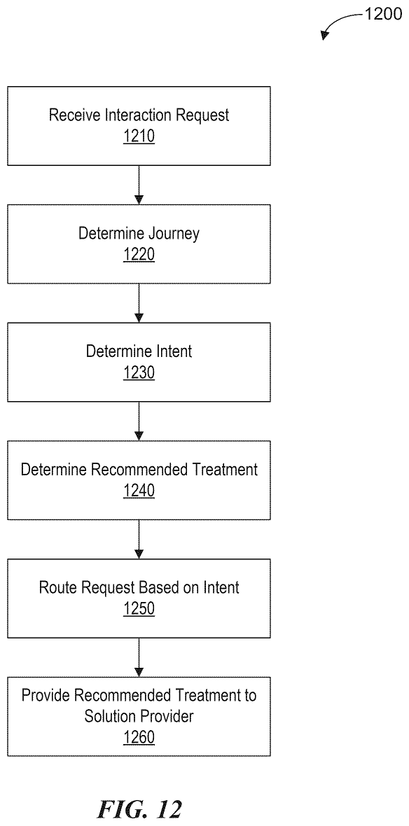

FIG. 12 is a block diagram that illustrates an example process 1200 for determining and using intents and treatments according to some implementations. The process shown in FIG. 12 can be performed by a computer system. At operation 1210, the system can receive a user interaction request. The user interaction request can be, for example, a call, text message, chat, email, etc. At operation 1220, the system can determine a journey as described herein. At operation 1230, the system can, based on the journey, determine an intent for the user as described herein. In some implementations, the system can, additionally or alternatively, use information supplied by the user to determine customer intent, such as a user selection in a phone tree, chat window, etc. At operation 1240, the system can determine one or more recommended treatments for the user. At operation 1250, the system can route the request based on the determined intent. At operation 1260, the system can provide the one or more recommended treatments to a solution provider who interacts with the user.

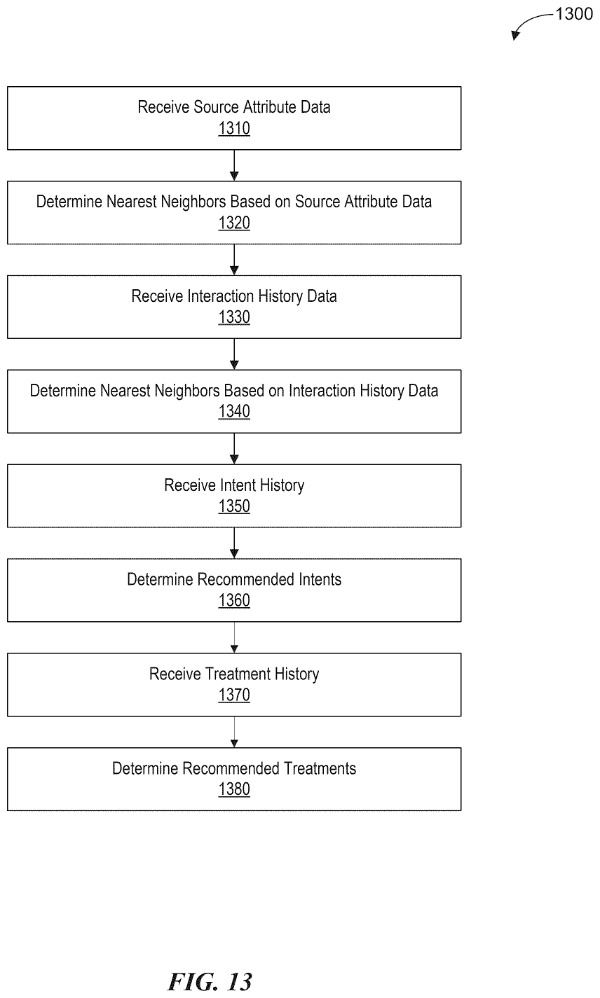

FIG. 13 is a block diagram that illustrates an example process 1300 for determining intents and treatments according to some implementations. The process shown in FIG. 13 can be carried out by a computer system. At operation 1310, the system can receive source (e.g., user) attribute data. At operation 1320, the system can determine nearest neighbors (e.g., similar sources) based on the source attribute data. At operation 1330, the system can receive interaction history data. At operation 1340, the system can determine nearest neighbors based on the interaction history data. In some implementations, the system may only perform operation 1340 for sources that were identified as nearest neighbors at operation 1320. At operation 1350, the system can receive an intent history. At operation 1360, the system can determine one or more recommended intents based on the nearest neighbors determined at operation 1340 and the intent history. At operation 1370, the system can receive a treatment history. At operation 1380, the system can determine one or more recommended treatment based on the nearest neighbors determined at operation 1340 and the treatment history.

### Computer System

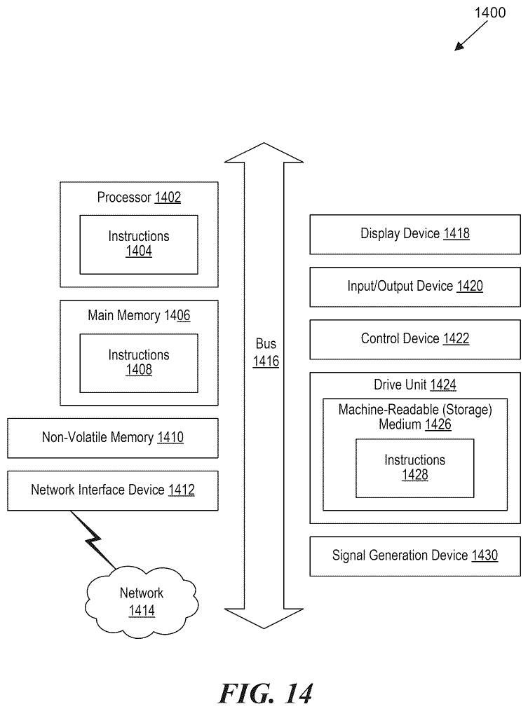

FIG. 14 is a block diagram that illustrates an example of a computer system 1400 in which at least some operations described herein can be implemented. As shown, the computer system 1400 can include: one or more processors 1402, main memory 1406, non-volatile memory 1410, a network interface device 1412, a video display device 1418, an input/output device 1420, a control device 1422 (e.g., keyboard and pointing device), a drive unit 1424 that includes a machine-readable (storage) medium 1426, and a signal generation device 1430 that are communicatively connected to a bus 1416. The bus 1416 represents one or more physical buses and/or point-to-point connections that are connected by appropriate bridges, adapters, or controllers. Various common components (e.g., cache memory) are omitted from FIG. 14 for brevity. Instead, the computer system 1400 is intended to illustrate a hardware device on which components illustrated or described relative to the examples of the figures and any other components described in this specification can be implemented.

The computer system 1400 can take any suitable physical form. For example, the computing system 1400 can share a similar architecture as that of a server computer, personal computer (PC), tablet computer, mobile telephone, game console, music player, wearable electronic device, network-connected (“smart”) device (e.g., a television or home assistant device), AR/VR systems (e.g., head-mounted display), or any electronic device capable of executing a set of instructions that specify action(s) to be taken by the computing system 1400. In some implementations, the computer system 1400 can be an embedded computer system, a system-on-chip (SOC), a single-board computer system (SBC), or a distributed system such as a mesh of computer systems, or it can include one or more cloud components in one or more networks. Where appropriate, one or more computer systems 1400 can perform operations in real time, in near real time, or in batch mode.

The network interface device 1412 enables the computing system 1400 to mediate data in a network 1414 with an entity that is external to the computing system 1400 through any communication protocol supported by the computing system 1400 and the external entity. Examples of the network interface device 1412 include a network adapter card, a wireless network interface card, a router, an access point, a wireless router, a switch, a multilayer switch, a protocol converter, a gateway, a bridge, a bridge router, a hub, a digital media receiver, and/or a repeater, as well as all wireless elements noted herein.

The memory (e.g., main memory 1406, non-volatile memory 1410, machine-readable medium 1426) can be local, remote, or distributed. Although shown as a single medium, the machine-readable medium 1426 can include multiple media (e.g., a centralized/distributed database and/or associated caches and servers) that store one or more sets of instructions 1428. The machine-readable medium 1426 can include any medium that is capable of storing, encoding, or carrying a set of instructions for execution by the computing system 1400. The machine-readable medium 1426 can be non-transitory or comprise a non-transitory device. In this context, a non-transitory storage medium can include a device that is tangible, meaning that the device has a concrete physical form, although the device can change its physical state. Thus, for example, non-transitory refers to a device remaining tangible despite this change in state.

Although implementations have been described in the context of fully functioning computing devices, the various examples are capable of being distributed as a program product in a variety of forms. Examples of machine-readable storage media, machine-readable media, or computer-readable media include recordable-type media such as volatile and non-volatile memory 1410, removable flash memory, hard disk drives, optical disks, and transmission-type media such as digital and analog communication links.

In general, the routines executed to implement examples herein can be implemented as part of an operating system or a specific application, component, program, object, module, or sequence of instructions (collectively referred to as “computer programs”). The computer programs typically comprise one or more instructions (e.g., instructions 1404, 1408, 1428) set at various times in various memory and storage devices in computing device(s). When read and executed by the processor 1402, the instruction(s) cause the computing system 1400 to perform operations to execute elements involving the various aspects of the disclosure.

### Remarks

The terms “example,” “embodiment,” and “implementation” are used interchangeably. For example, references to “one example” or “an example” in the disclosure can be, but not necessarily are, references to the same implementation; and such references mean at least one of the implementations. The appearances of the phrase “in one example” are not necessarily all referring to the same example, nor are separate or alternative examples mutually exclusive of other examples. A feature, structure, or characteristic described in connection with an example can be included in another example of the disclosure. Moreover, various features are described that can be exhibited by some examples and not by others. Similarly, various requirements are described that can be requirements for some examples but not for other examples.

The terminology used herein should be interpreted in its broadest reasonable manner, even though it is being used in conjunction with certain specific examples of the invention. The terms used in the disclosure generally have their ordinary meanings in the relevant technical art, within the context of the disclosure, and in the specific context where each term is used. A recital of alternative language or synonyms does not exclude the use of other synonyms. Special significance should not be placed upon whether or not a term is elaborated or discussed herein. The use of highlighting has no influence on the scope and meaning of a term. Further, it will be appreciated that the same thing can be said in more than one way.

Unless the context clearly requires otherwise, throughout the description and the claims, the words “comprise,” “comprising,” and the like are to be construed in an inclusive sense, as opposed to an exclusive or exhaustive sense—that is to say, in the sense of “including, but not limited to.” As used herein, the terms “connected,” “coupled,” and any variants thereof mean any connection or coupling, either direct or indirect, between two or more elements; the coupling or connection between the elements can be physical, logical, or a combination thereof. Additionally, the words “herein,” “above,” “below,” and words of similar import can refer to this application as a whole and not to any particular portions of this application. Where context permits, words in the above Detailed Description using the singular or plural number may also include the plural or singular number, respectively. The word “or” in reference to a list of two or more items covers all of the following interpretations of the word: any of the items in the list, all of the items in the list, and any combination of the items in the list. The term “module” refers broadly to software components, firmware components, and/or hardware components.

While specific examples of technology are described above for illustrative purposes, various equivalent modifications are possible within the scope of the invention, as those skilled in the relevant art will recognize. For example, while processes or blocks are presented in a given order, alternative implementations can perform routines having steps, or employ systems having blocks, in a different order, and some processes or blocks may be deleted, moved, added, subdivided, combined, and/or modified to provide alternative or sub-combinations. Each of these processes or blocks can be implemented in a variety of different ways. Also, while processes or blocks are at times shown as being performed in series, these processes or blocks can instead be performed or implemented in parallel, or can be performed at different times. Further, any specific numbers noted herein are only examples such that alternative implementations can employ differing values or ranges.

Details of the disclosed implementations can vary considerably in specific implementations while still being encompassed by the disclosed teachings. As noted above, particular terminology used when describing features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed herein, unless the above Detailed Description explicitly defines such terms. Accordingly, the actual scope of the invention encompasses not only the disclosed examples but also all equivalent ways of practicing or implementing the invention under the claims. Some alternative implementations can include additional elements to those implementations described above or include fewer elements.

Any patents and applications and other references noted above, and any that may be listed in accompanying filing papers, are incorporated herein by reference in their entireties, except for any subject matter disclaimers or disavowals, and except to the extent that the incorporated material is inconsistent with the express disclosure herein, in which case the language in this disclosure controls. Aspects of the invention can be modified to employ the systems, functions, and concepts of the various references described above to provide yet further implementations of the invention.

To reduce the number of claims, certain implementations are presented below in certain claim forms, but the applicant contemplates various aspects of an invention in other forms. For example, aspects of a claim can be recited in a means-plus-function form or in other forms, such as being embodied in a computer-readable medium. A claim intended to be interpreted as a means-plus-function claim will use the words “means for.” However, the use of the term “for” in any other context is not intended to invoke a similar interpretation. The applicant reserves the right to pursue such additional claim forms either in this application or in a continuing application.

What is claimed is:

1. A computer-implemented method comprising:
receiving attribute data comprising attributes for a plurality of sources;
generating, based on the attribute data, a plurality of period attributes vectors, each period attributes vector of the plurality of period attributes vectors corresponding to a source of the plurality of sources;
reducing a number of dimensions of each period attribute vector of the plurality of period attributes vectors to generate a transformed plurality of period attributes vectors;
determining, based on the transformed plurality of period attributes vectors, a first set of approximate nearest neighbors;
receiving interaction data for a plurality of interactions associated with the first set of approximate nearest neighbors;
determining word embeddings for each interaction included in the interaction data, wherein determining the word embeddings comprises providing an interaction transcript to a machine learning model, wherein the machine learning model is a large language model, and wherein the large language model is configured to output a summary of the interaction transcript;
determining, from the first set of approximate nearest neighbors, a second set of approximate nearest neighbors based on the word embeddings;
receiving historical intents data;
generating a matrix of historical intents based on the historical intents data;
receiving historical treatments data;
generating a matrix of historical treatments based on the historical treatments data;
determining, based on the matrix of historical intents and the second set of approximate nearest neighbors, one or more recommended intents; and
determining, based on the matrix of historical treatments and the second set of approximate nearest neighbors, one or more recommended treatments.

2. A computer-implemented method comprising:
generating, based on user attribute data, a plurality of period attributes vectors, each period attributes vector of the plurality of period attributes vectors corresponding to a user of a plurality of users;
determining, based on the plurality of period attributes vectors, a first set of nearest neighbors;
generating, based on interaction data, a word embeddings matrix;
identifying, using the word embeddings matrix, a second set of nearest neighbors, wherein the second set of nearest neighbors is a subset of the first set of nearest neighbors;
computing, using historical user intents data, a historical user intents matrix; and
generating, based on the second set of nearest neighbors and the historical user intents matrix, one or more recommended intents for a user.

3. The computer-implemented method of claim 2, wherein the one or more recommended intents comprise a vector, wherein the vector comprises a plurality of next recommended intents, each next recommended intent of the plurality of next recommended intents having a probability associated therewith.

4. The computer-implemented method of claim 2, further comprising:
determining, using historical user treatments data, a historical user treatments matrix; and
determining, based on the historical user treatments matrix, one or more recommended treatments for the user.

5. The computer-implemented method of claim 4, further comprising providing the one or more recommended treatments to a solution provider in communication with the user.

6. The computer-implemented method of claim 2, wherein determining the first set of nearest neighbors comprises determining an approximate first set of nearest neighbors.

7. The computer-implemented method of claim 2, wherein determining the second set of nearest neighbors comprises determining an approximate second set of nearest neighbors.

8. The computer-implemented method of claim 2, further comprising:
receiving a user interaction request from the user; and
routing the user to a support representative based at least in part on a most likely intent of the one or more recommended intents.

9. The computer-implemented method of claim 2, wherein determining the first set of nearest neighbors comprises transforming each period attributes vector of the plurality of period attributes vectors.

10. The computer-implemented method of claim 9, wherein transforming each period attributes vector comprises performing principal components analysis on the plurality of period attributes vectors.

11. The computer-implemented method of claim 2, wherein determining the first set of nearest neighbors comprises determining a plurality of Manhattan distances between pairs of vectors of the plurality of period attributes vectors.

12. A non-transitory, computer-readable storage medium comprising instructions recorded thereon, wherein the instructions when executed by at least one data processor of a system, cause the system to:
generate, based on user attribute data, a plurality of period attributes vectors, each period attributes vector of the plurality of period attributes vectors corresponding to a user of a plurality of users;
determine, based on the plurality of period attributes vectors, a first set of nearest neighbors;
generate, based on interaction data, a word embeddings matrix;
determine, using the word embeddings matrix, a second set of nearest neighbors, wherein the second set of nearest neighbors is a subset of the first set of nearest neighbors;
determine, using historical user intents data, a historical user intents matrix; and
determine, based on the second set of nearest neighbors and the historical user intents matrix, one or more recommended intents for a user.

13. The non-transitory, computer-readable storage medium of claim 12, wherein the one or more recommended intents comprise a vector, wherein the vector comprises a plurality of next recommended intents, each next recommended intent of the plurality of next recommended intents having a probability associated therewith.

14. The non-transitory, computer-readable storage medium of claim 12, further comprising instructions to cause the system to:
determine, using historical user treatments data, a historical user treatments matrix; and
determine, based on the historical user treatments matrix, one or more recommended treatments for the user.

15. The non-transitory, computer-readable storage medium of claim 14, further comprising instructions to cause the system to:
provide the one or more recommended treatments to a solution provider in communication with the user.

16. The non-transitory, computer-readable storage medium of claim 12, wherein determining the first set of nearest neighbors comprises determining an approximate first set of nearest neighbors.

17. The non-transitory, computer-readable storage medium of claim 12, wherein determining the second set of nearest neighbors comprises determining an approximate second set of nearest neighbors.

18. The non-transitory, computer-readable storage medium of claim 12, further comprising instructions to cause the system to:
receive a user interaction request from the user; and
route the user to a support representative based at least in part on a most likely intent of the one or more recommended intents.

19. The non-transitory, computer-readable storage medium of claim 12, wherein determining the first set of nearest neighbors comprises transforming each period attributes vector of the plurality of period attributes vectors.

20. The non-transitory, computer-readable storage medium of claim 19, wherein transforming each period attributes vector comprises performing principal components analysis on the plurality of period attributes vectors.
